(19) United States
(12) Patent Application Publication
(10) Pub. No.: US 2022/0328487 A1
(43) Pub. Date: Oct. 13, 2022

(54) SEMICONDUCTOR DEVICE AND ELECTRONIC DEVICE

(71) Applicant: SEMICONDUCTOR ENERGY LABORATORY CO., LTD., ATSUGI-SHI, KANAGAWA-KEN (JP)

(72) Inventors: Hajime KIMURA, Atsugi, Kanagawa (JP); Tatsuya ONUKI, Atsugi, Kanagawa (JP); Hitoshi KUNITAKE, Isehara, Kanagawa (JP)

(21) Appl. No.: 17/634,270

(22) PCT Filed: Aug. 17, 2020
(86) PCT No.: PCT/IB2020/057716

§ 371 Date: Feb. 10, 2022

(30) Foreign Application Priority Data
Aug. 29, 2019 (JP) 2019-156245
Dec. 5, 2019 (JP) 2019-220154

(51) Int. Cl. H01L 27/108

(52) U.S. Cl. CPC H01L 27/108

(57) ABSTRACT

A semiconductor device with a novel structure is provided. One embodiment of the present invention is a semiconductor device including a memory module. The memory module includes a first memory cell, a first wiring, and a second wiring and a third wiring that include a metal oxide. The first memory cell includes a read transistor and a rewrite transistor. The first wiring includes a region functioning as a back gate of the read transistor and a region where the second wiring functions as a conductor. The second wiring includes a region functioning as a channel formation region of the read transistor, a region functioning as a back gate of the rewrite transistor, and a region where the third wiring functions as a conductor. The third wiring includes a region functioning as a channel formation region of the rewrite transistor and a region functioning as a conductor.

### TECHNICAL FIELD

One embodiment of the present invention relates to a semiconductor device and an electronic device.

Note that one embodiment of the present invention is not limited to the above technical field. The technical field of one embodiment of the invention disclosed in this specification and the like relates to an object, a driving method, or a manufacturing method. Alternatively, the present invention relates to a process, a machine, manufacture, or a composition of matter. In particular, one embodiment of the present invention relates to a semiconductor device, a display device, a light-emitting device, a power storage device, a memory device, a driving method thereof, or a manufacturing method thereof.

In this specification and the like, a semiconductor device means an element, a circuit, a device, or the like that can function by utilizing semiconductor characteristics. For example, a semiconductor element such as a transistor or a diode is a semiconductor device. For another example, a circuit including a semiconductor element is a semiconductor device. For another example, a device provided with a circuit including a semiconductor element is a semiconductor device.

### BACKGROUND ART

Electronic devices including semiconductor devices, such as mobile devices (e.g., smartphones, tablets, and e-book readers), personal computers, and servers are required to handle large volumes of data. Thus, semiconductor devices need a large memory capacity, low power consumption, and fast processing time.

In particular, in recent years, the amount of data handled in the aforementioned electronic devices has increased with an increasing number of applications that deal with high-resolution images, moving images, sound, and the like. Semiconductor devices with a large memory capacity have been demanded accordingly. Patent Document 1 discloses a semiconductor device in which memory cells are stacked three-dimensionally. In addition, a technique for reducing the size of a circuit included in a semiconductor device has been required to achieve a semiconductor device with a large memory capacity without change in the chip size of the semiconductor device.

### REFERENCE

### Patent Document

[Patent Document 1] Japanese Published Patent Application No. 2008-258458

### SUMMARY OF THE INVENTION

### Problems to be Solved by the Invention

An application that operates in an electronic device is required to easily handle large volumes of data of images, sound, and the like on the Internet or a network. A portable electronic device, such as a mobile device, needs to accomplish lower power consumption to achieve longer-term use. An electronic device can employ a technique for reducing power, such as power gating. However, data that is being used needs to be saved to utilize a power reduction technique such as power gating.

For example, in a NAND flash memory known as a semiconductor device, data other than data at an address specified for data rewriting needs to be updated. Thus, a NAND flash memory or the like takes much processing time to write a large amount of data, and there is a problem in that power consumption increases in accordance with the amount of data. Moreover, a NAND flash memory or the like requires a high potential for data writing, and thus has a problem of high power consumption.

In view of the above problems, an object of one embodiment of the present invention is to provide a memory device with a novel structure. Another object of one embodiment of the present invention is to provide a memory device with reduced power consumption. Another object of one embodiment of the present invention is to provide a memory device with a short rewriting time.

Note that the description of these objects does not preclude the existence of other objects. One embodiment of the present invention does not have to achieve all these objects. Other objects are apparent from the description of the specification, the drawings, the claims, and the like, and other objects can be derived from the description of the specification, the drawings, the claims, and the like.

### Means for Solving the Problems

One embodiment of the present invention is a semiconductor device including a memory module. The memory module includes a first memory cell, a first wiring, a second wiring, and a third wiring. The second wiring and the third wiring each include a metal oxide. The first memory cell includes a first read transistor and a first rewrite transistor. The first wiring includes a region functioning as a back gate of the first read transistor and a region where the second wiring functions as a conductor. The second wiring includes a region functioning as a channel formation region of the first read transistor, a region functioning as a back gate of the first rewrite transistor, and a region where the third wiring functions as a conductor. The third wiring includes a region functioning as a channel formation region of the first rewrite transistor and a region functioning as a conductor.

In the above structure, the first rewrite transistor and the first read transistor are preferably formed in the same opening, and the second wiring including the channel formation region of the first read transistor is preferably formed inward from the third wiring including the channel formation region of the first rewrite transistor, with an insulating layer therebetween.

An electronic device including the above-described semiconductor device and a housing is preferable.

### Effect of the Invention

One embodiment of the present invention can provide a memory device with a novel structure. Another embodiment of the present invention can provide a memory device with reduced power consumption. Another embodiment of the present invention can provide a memory device with a short rewriting time.

Note that the effects of one embodiment of the present invention are not limited to the effects listed above. The effects listed above do not preclude the existence of other effects. Note that the other effects are effects that are not described in this section and will be described below. The other effects not described in this section will be apparent from the description of the specification, the drawings, and the like and can be derived as appropriate from the description by those skilled in the art. One embodiment of the present invention has at least one effect of the effects listed above and/or the other effects. Accordingly, depending on the case, one embodiment of the present invention does not have the effects listed above in some cases.

### BRIEF DESCRIPTION OF THE DRAWINGS

FIG. 1A to FIG. 1C are circuit diagrams showing configuration examples of a semiconductor device.

FIG. 2 is a circuit diagram showing a configuration example of a semiconductor device.

FIG. 3 is an equivalent circuit diagram of a memory string.

FIG. 4 is an equivalent circuit diagram of a memory string.

FIG. 5 is an equivalent circuit diagram of a memory string.

FIG. 6 is an equivalent circuit diagram of a memory string.

FIG. 7 is a timing chart showing an operation example of a semiconductor device.

FIG. 8 is a timing chart showing an operation example of a semiconductor device.

FIG. 9 is a timing chart showing an operation example of a semiconductor device.

FIG. 10 is a circuit diagram showing a configuration example of a semiconductor device.

FIG. 11 is a timing chart showing an operation example of a semiconductor device.

FIG. 12 is a timing chart showing an operation example of a semiconductor device.

FIG. 13A and FIG. 13B are block diagrams showing examples of a memory device.

FIG. 14 is a circuit diagram showing a configuration example of a semiconductor device.

FIG. 15 is a circuit diagram showing a configuration example of a semiconductor device.

FIG. 16 is a circuit diagram showing a configuration example of a semiconductor device.

FIG. 17A and FIG. 17B are a top view and a cross-sectional view for describing a structure example of a semiconductor device.

FIG. 18A and FIG. 18B are cross-sectional views for describing a manufacturing example of a semiconductor device.

FIG. 19A and FIG. 19B are cross-sectional views for describing a manufacturing example of a semiconductor device.

FIG. 20A and FIG. 20B are cross-sectional views for describing a manufacturing example of a semiconductor device.

FIG. 21A and FIG. 21B are cross-sectional views for describing a manufacturing example of a semiconductor device.

FIG. 22A and FIG. 22B are cross-sectional views for describing a manufacturing example of a semiconductor device.

FIG. 23A and FIG. 23B are cross-sectional views for describing a manufacturing example of a semiconductor device.

FIG. 24A and FIG. 24B are cross-sectional views for describing a manufacturing example of a semiconductor device.

FIG. 25A and FIG. 25B are cross-sectional views for describing a manufacturing example of a semiconductor device.

FIG. 26A and FIG. 26B are cross-sectional views for describing a manufacturing example of a semiconductor device.

FIG. 27A and FIG. 27B are cross-sectional views for describing a manufacturing example of a semiconductor device.

FIG. 28 is a cross-sectional view for describing a manufacturing example of a semiconductor device.

FIG. 29 is a cross-sectional view for describing a manufacturing example of a semiconductor device.

FIG. 30 is a cross-sectional view for describing a manufacturing example of a semiconductor device.

FIG. 31 is a diagram for describing a semiconductor device.

FIG. 32A and FIG. 32B are diagrams for describing a semiconductor device.

FIG. 33A and FIG. 33B are diagrams for describing a semiconductor device.

FIG. 34 is a diagram describing a semiconductor device.

FIG. 35 is a diagram describing an operation example of a semiconductor device.

FIG. 36 is a diagram describing an operation example of a semiconductor device.

FIG. 37 is a diagram describing an operation example of a semiconductor device.

FIG. 38 is a diagram describing an operation example of a semiconductor device.

FIG. 39 is a diagram describing an operation example of a semiconductor device.

FIG. 40 is a diagram describing an operation example of a semiconductor device.

FIG. 41 is a block diagram describing a CPU.

FIG. 42A to FIG. 42E are perspective views showing examples of electronic device.

FIG. 43A to FIG. 43F are perspective views showing examples of electronic device.

### MODE FOR CARRYING OUT THE INVENTION

### Embodiment 1

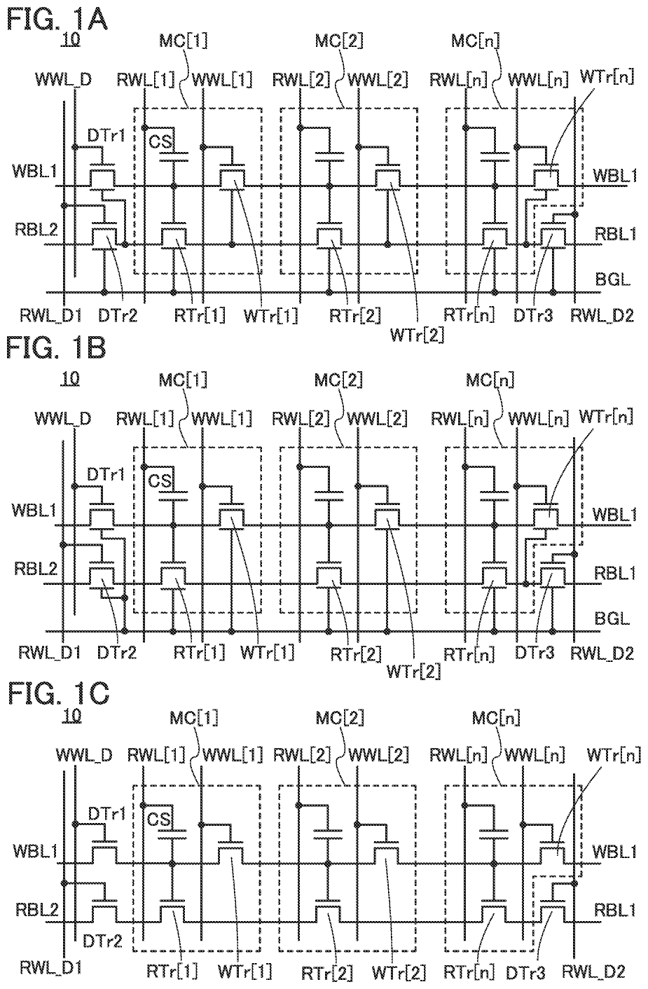

In this embodiment, a semiconductor device in which the time for rewriting in memory cells is shortened will be described with reference to FIG. 1 to FIG. 12.

First, the circuit configuration of the semiconductor device will be described with reference to FIG. 1A. The semiconductor device illustrated in FIG. 1A is a memory module 10 including n memory cells. The memory module 10 includes a memory cell MC[1] to a memory cell MC[n] , a selection transistor DTr1, a selection transistor DTr2, a selection transistor DTr3, a wiring WWL_D, a wiring RWL_D1, a wiring RWL_D2, a wiring WWL[1] to a wiring WWL[n], a wiring RWL[1] to a wiring RWL[n], a wiring WBL1, a wiring RBL1, and a wiring RBL2. The wirings WWL (the wiring WWL[1] to the wiring WWL[n]) function as rewrite word lines, the wirings RWL (the wiring RWL[1] to the wiring RWL[n]) function as read word lines, the wiring WBL1 functions as a rewrite bit line, and the wiring RBL1 and the wiring RBL2 function as read bit lines. Note that n is an integer greater than or equal to 2.

The memory cell MC[1] to the memory cell MC[n] each include a transistor WTr and a transistor RTr. The transistors WTr (a transistor WTr[1] to a transistor WTr[n]) and the transistors RTr (a transistor RTr[1] to a transistor RTr[n]) illustrated in FIG. 1A are preferably transistors with low off-state current. The use of transistors with low off-state current as the transistor WTr and the transistor RTr can ensure independence of data retained in the adjacent memory nodes. The transistor WTr and the transistor RTr are each preferably a transistor including a back gate. Application of a potential to the back gates enables control of the threshold voltages of the transistor WTr and the transistor RTr.

FIG. 1A shows an example in which the memory cell MC[1] to the memory cell MC[n] are connected in series. The selection transistor DTr1 for rewriting data stored in the memory cell is preferably connected to one end of the memory cell MC[1] to the memory cell MC[n] connected in series. The selection transistor DTr2 for reading data stored in the memory cell is preferably connected to the one end of the memory cell MC[1] to the memory cell MC[n] connected in series, and the selection transistor DTr3 for reading data stored in the memory cell is preferably connected to the other end. FIG. 1A shows an example in which the selection transistor DTr1 and the selection transistor DTr2 are connected to the memory cell MC[1].

Each of the memory cells includes a capacitor CS and a memory node in addition to the transistor WTr and the transistor RTr. The transistor WTr functions as a rewrite transistor, and the transistor RTr functions as a read transistor.

The memory node is formed by electrical connection between one of a source and a drain of the transistor WTr, a gate of the transistor RTr, and one electrode of the capacitor CS. A gate of the transistor WTr is electrically connected to the wiring WWL, and the other electrode of the capacitor CS is electrically connected to the wiring RWL. For example, the other of a source and a drain of the transistor WTr[1] in the memory cell MC[1] is electrically connected to the memory node of the memory cell MC[2], which is connected in series to the memory cell MC[1].

One of a source and a drain of the selection transistor DTr1 is electrically connected to the wiring WBL1, the other of the source and the drain of the selection transistor DTr1 is electrically connected to the memory node of the memory cell MC[1], and a gate of the selection transistor DTr1 is electrically connected to the wiring WWL_D.

The other of a source and a drain of the transistor WTr[n] included in the memory cell MC[n] is electrically connected to the wiring WBL1. That is, one end of a string of the memory cells connected in series is electrically connected to the other end of the string of the memory cells through the selection transistor DTr1 and the wiring WBL1.

One of a source and a drain of the selection transistor DTr2 is electrically connected to the wiring RBL2, the other of the source and the drain of the selection transistor DTr2 is electrically connected to one of a source and a drain of the transistor RTr[1] of the memory cell MC[1], and a gate of the selection transistor DTr2 is electrically connected to the wiring RWL_D1.

The other of the source and the drain of the transistor RTr[1] included in the memory cell MC[1] is electrically connected to one of a source and a drain of the transistor RTr[2] included in the memory cell MC[2], which is connected in series to the memory cell MC[1].

The other of a source and a drain of the transistor RTr[n] included in the memory cell MC[n] is electrically connected to one of a source and a drain of the selection transistor DTr3. The other of the source and the drain of the selection transistor DTr3 is electrically connected to the wiring RBL1. A gate of the selection transistor DTr3 is electrically connected to the wiring RWL_D2. That is, the wiring RBL1 is electrically connected to, through the selection transistor DTr2, the transistors RTr included in the memory cells connected in series, and the transistor RTr[n] included in the memory cell MC[n] is electrically connected to, through the selection transistor DTr2, the wiring RBL2.

For example, a back gate of the transistor WTr[1] included in the memory cell MC[1] is electrically connected to a node connecting the other of the source and the drain of the transistor RTr[1] included in the memory cell MC[1] and the one of the source and the drain of the transistor RTr[2] included in the memory cell MC[2]. A back gate of the selection transistor DTr1 is electrically connected to a node connecting the other of the source and the drain of the selection transistor DTr2 and the one of the source and the drain of the transistor RTr[1] included in the memory cell MC[1].

A wiring BGL illustrated in FIG. 1A is electrically connected to back gates of the transistor RTr[1] to the transistor RTr[n] included in the memory cell MC[1] to the memory cell MC[n]. The selection transistor DTr2 and the selection transistor DTr3 also preferably include back gates like the transistor WTr[n], and as illustrated in FIG. 1A, the back gates of the selection transistor DTr2 and the selection transistor DTr3 are also preferably electrically connected to the wiring BGL.

In the memory module 10 with the above configuration, data in one of the memory cell MC[1] to the memory cell MC[n] can be rewritten through the transistors WTr connected in series and the memory nodes. Note that to rewrite data in the memory cell MC[j] (j is an integer greater than or equal to 1 and less than or equal to n) that is closer to the memory cell MC[1], data is preferably supplied from the wiring WBL1 through the selection transistor DTr1; whereas to rewrite data in the memory cell MC[j] that is closer to the memory cell MC[n], data is preferably supplied from the wiring WBL1 connected to the memory cell MC[n].

In the memory module 10 with the above configuration, data in one of the memory cell MC[1] to the memory cell MC[n] can be read through the transistors RTr connected in series. Note that to read data in the memory cell MC[j] that is closer to the memory cell MC[1], read data is preferably supplied to the wiring RBL1 through the selection transistor DTr2; whereas to read data in the memory cell MC[j] that is closer to the memory cell MC[n], read data is preferably supplied to the wiring RBL2 through the selection transistor DTr3 connected to the memory cell MC[n].

Note that a channel formation portion of the selection transistor DTr1, the memory node, and a channel formation region of the transistor WTr are semiconductor layers containing the same metal oxide. Note that when impurities such as hydrogen are added to the semiconductor layer containing the metal oxide, the resistance value decreases and the semiconductor layer can function as a wiring. When a positive electric field is applied to the semiconductor layer containing the metal oxide, the resistance value decreases and the semiconductor layer can function as a wiring. Thus, the semiconductor layer containing the metal oxide can be rephrased as a wiring.

Note that channel formation portions of the selection transistor DTr2 and the selection transistor DTr3, a channel formation region of the read transistor RTr, and the connection node between the transistors RTr are semiconductor layers containing a metal oxide. Thus, the semiconductor layer containing the metal oxide can be rephrased as a wiring.

The channel formation regions of the transistor WTr and the transistor RTr each preferably contain one or more metal oxides selected from indium, an element M (M is aluminum, gallium, yttrium, or tin, for example), and zinc, for example. In this case, the metal oxide functions as a wide gap semiconductor; thus, a transistor containing the metal oxide in its channel formation region exhibits extremely low off-state current characteristics. When a transistor with low off-state current characteristics is used as the transistor WTr for controlling data retention, the memory cell MC can retain data for a long time. As a result, the number of refreshing retained data can be reduced, leading to lower power consumption of the semiconductor device. A transistor containing a metal oxide in a channel formation region can be referred to as an OS transistor.

For the channel formation region of the transistor RTr, a material achieving high field-effect mobility of the transistor is preferably used. Using such a transistor allows the semiconductor device to operate faster. The channel formation region of the transistor RTr can contain one or more metal oxides selected from indium, an element M (M is aluminum, gallium, yttrium, or tin, for example), and zinc, or a semiconductor material such as silicon, for example.

The memory module 10 with a circuit configuration different from that in FIG. 1A will be described with reference to FIG. 1B. The example is shown in which the wiring BGL illustrated in FIG. 1B is electrically connected to back gates of the transistors WTr and the transistors RTr included in the memory cell MC[1] to the memory cell MC[n]. Application of a potential to the back gates enables control of the threshold voltages of the transistor WTr and the transistor RTr.

Unlike in the example shown in FIG. 1B, in the memory module 10, the wirings BGL may be electrically connected to the back gates of the transistors WTr and the transistors RTr included in the memory cell MC[1] to the memory cell MC[n] independently and supply different potentials to the respective back gates.

The memory module 10 with a circuit configuration different from that in FIG. 1B will be described with reference to FIG. 1C. In FIG. 1C, the transistor WTr or the transistor RTr is a transistor without a back gate.

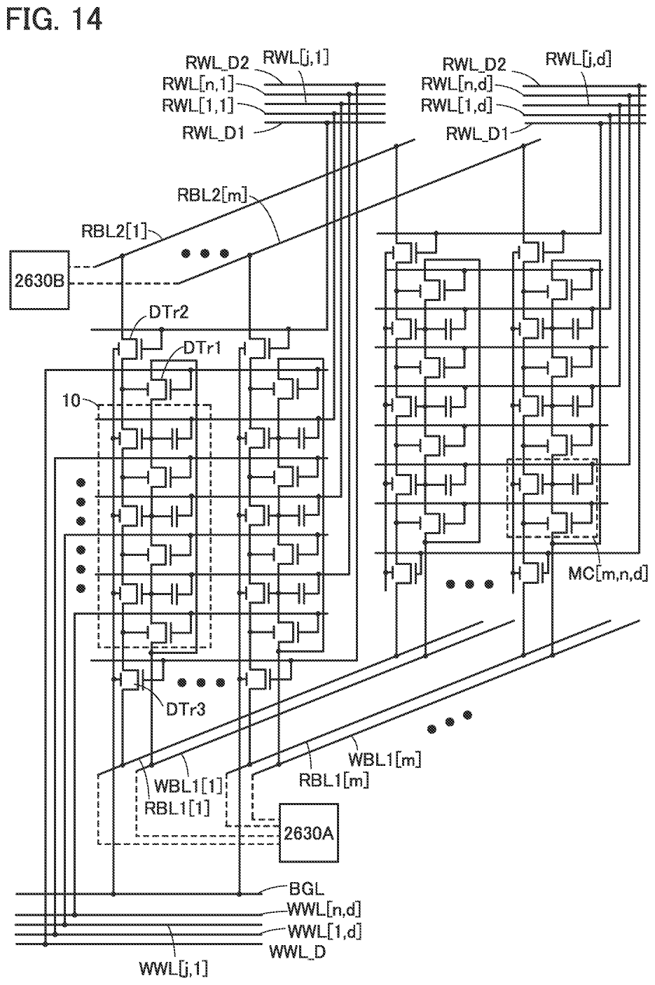

For example, when a metal oxide is used for the channel formation regions of the transistor WTr and the transistor RTr, the transistor WTr and the transistor RTr can be formed in the same opening. A wiring including the channel formation region of the transistor RTr is preferably formed inward from a wiring including the channel formation region of the transistor WTr with an insulating layer therebetween. The transistors WTr and the transistors RTr are preferably alternately formed in one opening. This structure will be described in detail with reference to FIG. 14 to FIG. 29.

The transistor WTr and the transistor RTr can be formed over a silicon substrate. When a metal oxide is used for the channel formation regions of the transistor RTr and the transistor WTr, the memory module 10 can be formed above the transistors formed over the silicon substrate. Accordingly, a semiconductor device with high data density per unit area is easily obtained by alternately forming the transistors WTr and the transistors RTr in one opening.

In the case where the manufacturing cost needs to be reduced by simplifying the manufacturing process, the plurality of transistors WTr and the plurality of transistors RTr are formed to be flat. By forming the transistor WTr and the transistor RTr over a silicon substrate at the same time, the manufacturing process is simplified and circuits having different functions can be mounted on the silicon substrate. A memory module including the transistors WTr and the transistors RTr can be formed over the circuits, which is suitable for mounting an embedded memory or the like. By forming the memory module over the circuits, the mount space can be reduced.

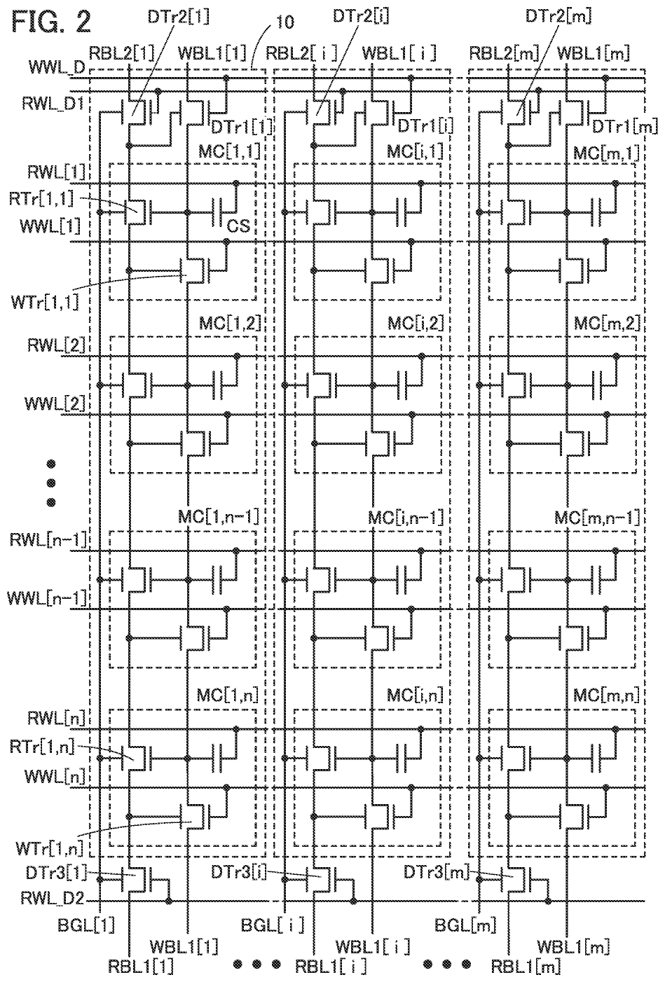

In a semiconductor device illustrated in FIG. 2, the memory modules 10 illustrated in FIG. 1A are arranged in m columns, and the wiring RWL and the wiring WWL are electrically connected to and shared between the memory cells MC in the same row. That is, the semiconductor device illustrated in FIG. 2 is a semiconductor device that can be represented by a matrix of n rows and m columns and includes a memory cell MC[1,1] to a memory cell MC[m,n]. Although not shown in FIG. 2 for simplicity, considering the depth direction enables the semiconductor device to include a memory cell MC[1,1,1] to a memory cell MC[m,n,d] that are arranged in three dimensions. In Embodiment 2, an example of the semiconductor device including the memory cell MC[1,1,1] to the memory cell MC[m,n,d] that are arranged in three dimensions will be described in detail. Note that m, n, and d are each an integer greater than or equal to 2.

The semiconductor device illustrated in FIG. 2 includes the wiring WWL_D, the wiring RWL_D1, the wiring RWL_D2, the wiring RWL[1] to the wiring RWL[n], the wiring WWL[1] to the wiring WWL[n], a wiring RBL1[1] to a wiring RBL1[m], a wiring RBL2[1] to a wiring RBL2[m], a wiring WBL1[1] to a wiring WBL1[m], and a wiring BGL[1] to a wiring BGL[m].

Specifically, the other electrode of the capacitor CS in the memory cell MC[i,j] (not illustrated) is electrically connected to the wiring RWL[j], and a gate of a transistor WTr[i,j] in the memory cell MC[i,j] is electrically connected to the wiring WWL[j]. The wiring WBL1[i] is electrically connected to one of a source and a drain of a selection transistor DTr1[i] and the other of a source and a drain of a transistor WTr[i,n] in the memory cell MC[i,n]. The wiring RBL1[i] is electrically connected to the other of a source and a drain of a transistor RTr[i,n] in the memory cell MC[i ,n]. The wiring RBL2[i] is electrically connected to one of a source and a drain of the transistor RTr in the memory cell MC[i,1]. In addition, i is an integer greater than or equal to 1 and less than or equal to m, and j is an integer greater than or equal to 1 and less than or equal to n.

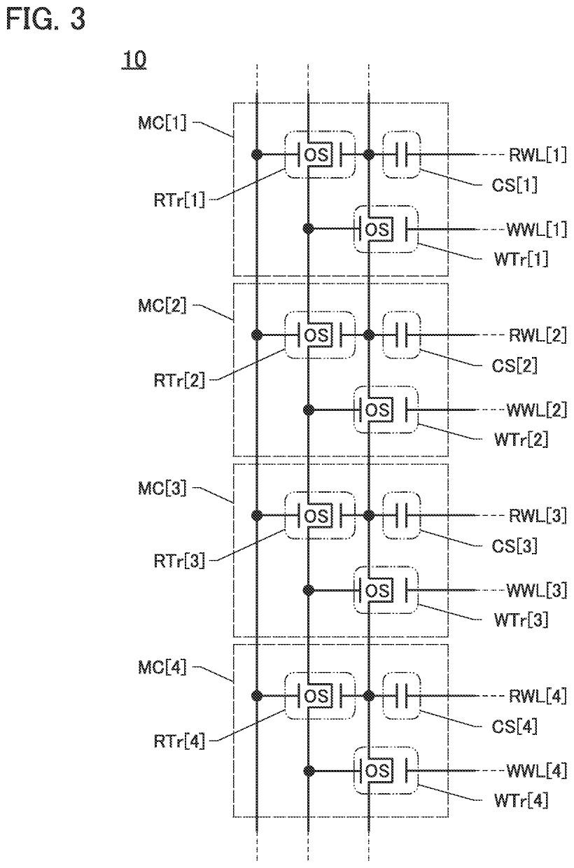

In FIG. 3, the transistor WTr, the transistor RTr, and the capacitor CS included in the memory cell MC[1] are denoted as the transistor WTr[1], the transistor RTr[1], and a capacitor CS[1]. The transistors WTr, the transistors RTr, and the capacitors CS included in the memory cell MC[2] to the memory cell MC[4] are denoted in a similar manner.

The number of memory cells MC included in the memory module 10 is not limited to four. Given that the number of memory cells MC included in the memory module 10 is n, n is an integer greater than or equal to 2.

The expression “a structure in which a plurality of memory cells MC are connected in series” means that a drain (or a source) of the transistor WTr[k] included in the memory cell MC[k] (k is an integer greater than or equal to 1 and less than or equal to n−1) is electrically connected to a source (or a drain) of the transistor WTr[k+1] included in the memory cell MC[k+1], and a drain (or a source) of the transistor RTr[k] included in the memory cell MC[k] is electrically connected to a source (or a drain) of the transistor RTr[k+1] included in the memory cell MC[k+1].

For semiconductors in which channels of the transistor WTr and the transistor RTr are formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that the semiconductor used in the transistor may be a stack of semiconductors. In the case of stacking semiconductor layers, semiconductors having different crystal states may be used or different semiconductor materials may be used.

In particular, the transistor WTr is preferably an OS transistor including an oxide semiconductor, which is a metal oxide, in a semiconductor layer in which a channel is formed. An oxide semiconductor has a band gap of 2 eV or more and thus has extremely low off-state current. When an OS transistor is used as the transistor WTr, charge written to a node ND (also referred to as a “storage node”) can be retained for a long time. When an OS transistor is used as the transistor WTr, the memory cell MC can be referred to as an “OS memory”. Furthermore, the memory module 10 including the memory cell MC can also be referred to as an “OS memory”.

A NAND memory device including the OS memory is referred to as an “OS NAND type” or an “OS NAND memory device”. An OS NAND memory device in which a plurality of OS memories are stacked in the Z direction is referred to as a “3D OS NAND type” or a “3D OS NAND memory device”.

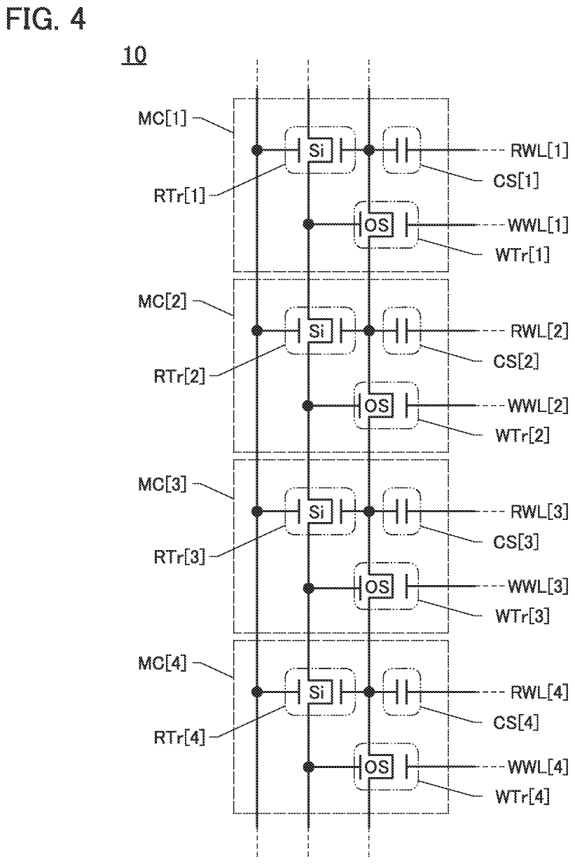

The transistor RTr may be a transistor including silicon in a semiconductor layer in which a channel is formed (also referred to as a “Si transistor”). The transistor RTr may be a Si transistor and the transistor WTr may be an OS transistor. FIG. 4 shows an equivalent circuit diagram of the memory module 10 in which OS transistors are used as the transistors WTr and Si transistors are used as the transistors RTr.

The OS memory can retain written data for a period of one year or longer, or even 10 years or longer after power supply is stopped. Thus, the OS memory can be regarded as a nonvolatile memory.

In the OS memory, the amount of written charge is less likely to change over a long period of time; hence, the OS memory can retain multilevel (multibit) data as well as binary (1-bit) data.

Furthermore, an OS memory employs a method in which charge is written to a node through the OS transistor; hence, high voltage, which a conventional flash memory requires, is unnecessary and a high-speed writing operation is possible. The OS memory does not require erase operation before data rewriting, which is performed in a flash memory. Furthermore, it is possible that the number of data writing and reading operations in the OS memory is substantially unlimited because charge injection and extraction into/from a floating gate or a charge trap layer are not performed. The OS memory is less likely to degrade than a conventional flash memory and can have high reliability.

Unlike a magnetoresistive random access memory (MRAM), a resistive random access memory (ReRAM), or the like, an OS memory has no change in the structure at the atomic level. Thus, an OS memory has higher rewrite endurance than a magnetoresistive random access memory and a resistive random access memory.

The off-state current of an OS transistor hardly increases even in a high-temperature environment. Specifically, the off-state current hardly increases even at an environment temperature higher than or equal to room temperature and lower than or equal to 200° C. In addition, the on-state current is unlikely to decrease even in a high-temperature environment. A memory device including the OS memory achieves stable operation and high reliability even in a high-temperature environment. An OS transistor has high withstand voltage between its source and drain. When OS transistors are used as transistors included in a semiconductor device, the semiconductor device achieves stable operation and high reliability even in a high-temperature environment.

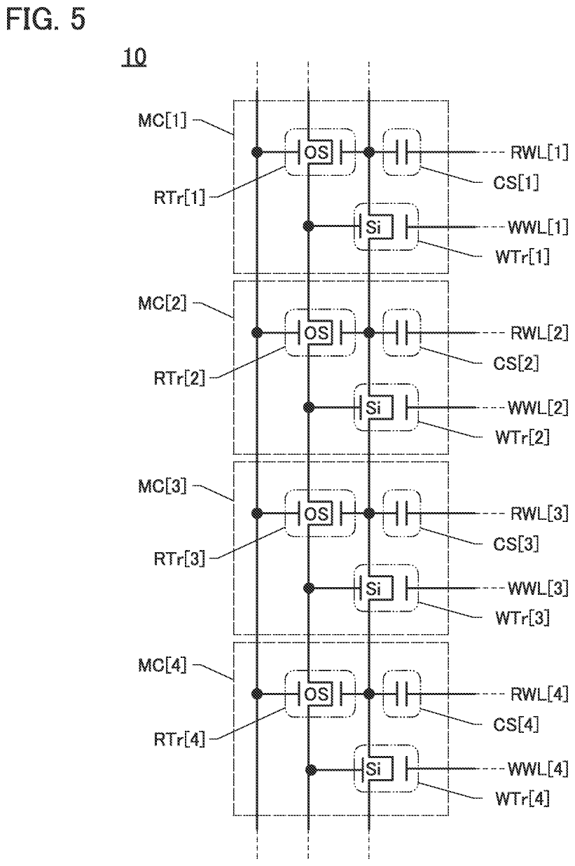

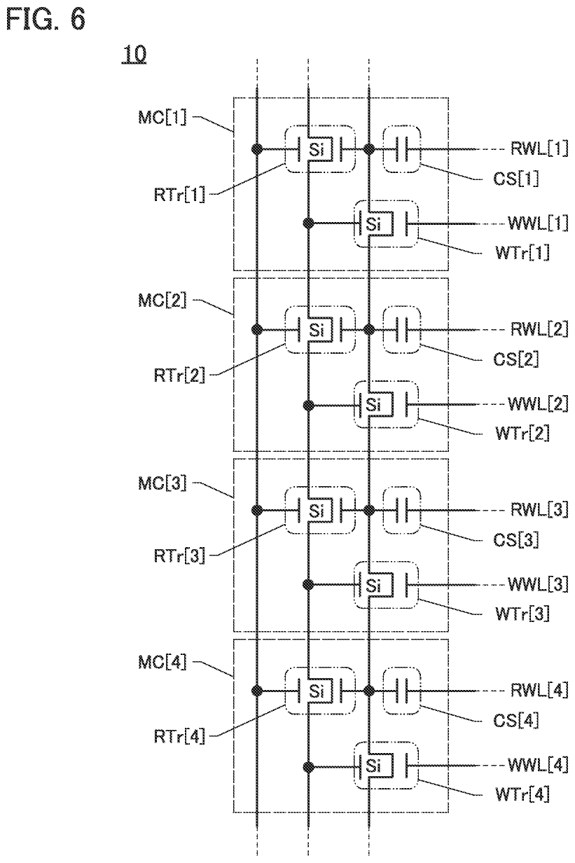

As illustrated in FIG. 5, Si transistors may be used as the transistors WTr and OS transistors may be used as the transistors RTr depending on the purpose, application, or the like. As illustrated in FIG. 6, Si transistors may be used as both the transistors WTr and the transistors RTr depending on the purpose, application, or the like.

When a plurality of memory cells MC are provided continuously in the Z direction as in the memory module 10, the memory capacity per unit area can be increased.

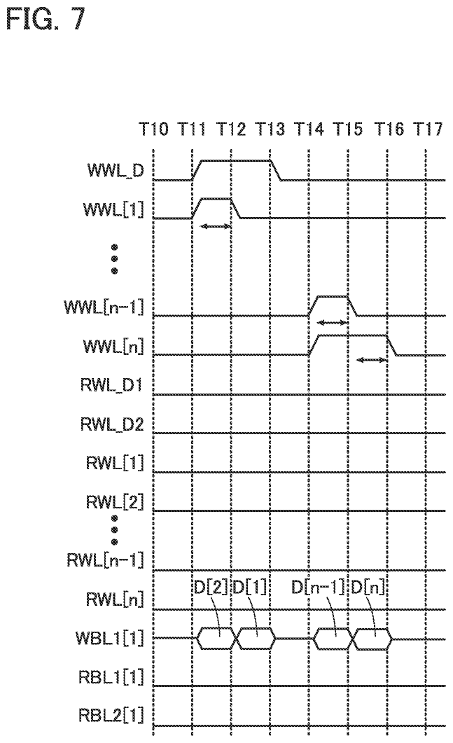

In the structure of data stored in the memory module included in the semiconductor device illustrated in FIG. 2, the data width is preferably represented in bits, the smallest unit of data. As an example, operation for rewriting data in the first row, the second row, the (n−1)-th row, and the n-th row will be described with reference to a timing chart in FIG. 7.

At Time T11, a selection transistor DTr1[1] to a selection transistor DTr1[m] are turned on by supply of “H” to the wiring WWL_D. The transistors WTr included in the memory cells MC[1,1] to MC[m,1] are turned on by supply of “H” to the wiring WWL[1]. The wirings WBL1[1] to WBL1[m] can supply data D[2] to the memory nodes of the memory cell MC[1,2] to the memory cell MC[m,2] through the selection transistor DTr1[1] to the selection transistor DTr1[m]. At this time, the data D[2] is also supplied to the memory nodes of the memory cell MC[1,1] to the memory cell MC[m,1]. The data D is preferably digital data with an m-bit data width. Alternatively, analog data may be supplied as the data D. Analog data is preferably controlled with a potential. The semiconductor device can store a drastically increased amount of data by handling analog data with different bits.

At Time T12, the transistors WTr included in the memory cells MC[1,1] to MC[m,1] are turned off by supply of “L” to the wiring WWL[1]. Thus, the data D[2] is retained in the memory nodes of the memory cell MC[1,2] to the memory cell MC[m,2]. Furthermore, by data D[1] supplied to the wiring WBL1[1] to the wiring WBL1[m], the data in the memory nodes of the memory cell MC[1,1] to the memory cell MC[m,1] can be rewritten through the selection transistor DTr1[1] to the selection transistor DTr1[m].

At Time T13, the selection transistor DTr1[1] to the selection transistor DTr1[m] are turned off by supply of “L” to the wiring WWL_D. Thus, the data D[1] is retained in the memory nodes of the memory cell MC[1,1] to the memory cell MC[m,1].

At Time T14, the transistors WTr included in the memory cell MC[1,n−1] to the memory cell MC[m,n−1] are turned on by supply of “H” to the wiring WWL[n−1]. The transistors WTr included in the memory cell MC[1,n] to the memory cell MC[m ,n] are turned on by supply of “H” to the wiring WWL[n]. By data D[n−1] supplied to the wiring WBL1[1] to the wiring WBL1[m], data in the memory nodes of the memory cell MC[1,n−1] to the memory cell MC[m,n−1] can be rewritten through the memory nodes of the memory cell MC[1,n] to the memory cell MC[m,n].

At Time T15, the transistors WTr included in the memory cell MC[1,n−1] to the memory cell MC[m,n−1] are turned off by supply of “L” to the wiring WWL[n−1]. Thus, the data D[n−1] is retained in the memory nodes of the memory cell MC[1,n−1] to the memory cell MC[m,n−1]. Moreover, the wiring WBL1[1] to the wiring WBL1[m] can supply data D[n] to the memory nodes of the memory cell MC[1,n] to the memory cell MC[m,n].

At Time T16, the transistors WTr included in the memory cells MC[1,n] to MC[m,n] are turned off by supply of “L” to the wiring WWL[n]. Thus, the data D[n] is retained in the memory nodes of the memory cells MC[1,n] to MC[m,n].

In the period from Time T10 to Time T17, when the wiring WWL_D and the wiring WWL[n] are supplied with “L”, a section interposed between a selection transistor DTr1[1,n] and a transistor WTr[1,n] can be brought into a floating state, for example.

In the period from Time T10 to Time T17, the wiring RWL_D1 and the wiring RWL_D2 are supplied with “L”. A section interposed between a selection transistor DTr2[1] and a selection transistor DTr3[1] can be brought into a floating state, for example. Since a potential supplied to the wiring RBL1 and the wiring RBL2 does not affect the memory module, the wiring RBL1 and the wiring RBL2 can be brought into a floating state. Therefore, power supplied to the wiring RBL1 and the wiring RBL2 can be reduced. Alternatively, a given potential may be supplied to the wiring RBL1 and the wiring RBL2.

In a NAND flash memory, to perform update in one of memory cells connected in series in a memory module, data in all the rows of the memory module needs to be updated. In contrast, with the configuration shown in this embodiment, data in a given row of the memory module can be rewritten, resulting in fast data rewriting.

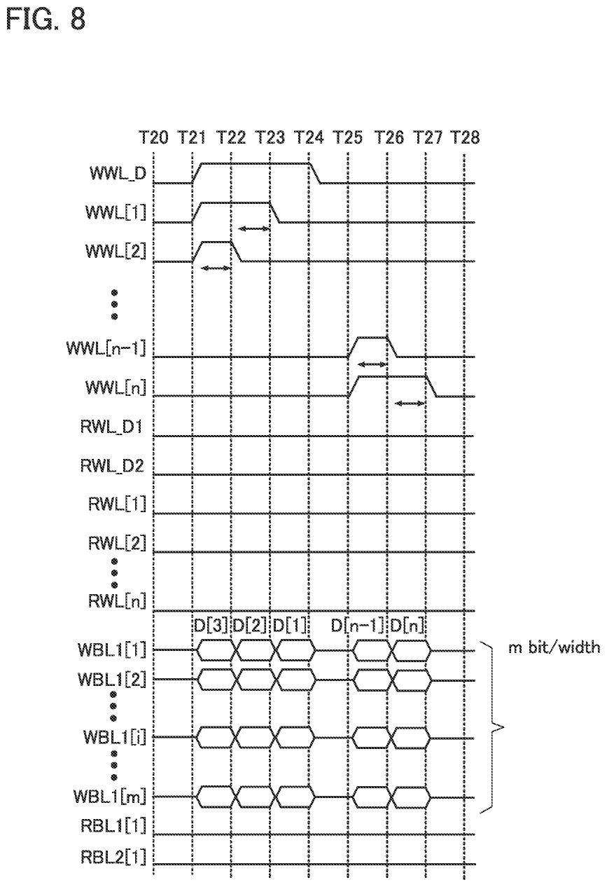

Next, the description is made on an example in which a plurality of memory modules included in the semiconductor device are connected through the wirings WWL, the wirings RWL, and the wiring WWL_D and data to be stored has an m-bit data width. As an example, operation for rewriting data in the first row, the second row, the third row, the (n−1)-th row, and the n-th row is described with reference to a timing chart in FIG. 8.

Basic operation is the same as the operation described with FIG. 7, and therefore the description thereof is not repeated; differences from FIG. 7 are described with FIG. 8. As an example, data rewriting in the third row is described with FIG. 8. In FIG. 8, in the period from Time T21 to Time T22, data D[3] is retained in the memory cell MC[1,3] to the memory cell MC[m,3] as data in the third row. In the memory module having a plurality of rows, a given row subjected to rewriting is preferably accessed through the closer one of the two memory cells MC: the first-row memory cell MC to which the selection transistor DTr1 is connected, and the n-th-row memory cell MC. The time for rewriting in memory cells depends on the number of rows from one end to the given row subjected to rewriting. Accordingly, access from the end closer to the given row subjected to rewriting leads to a shorter rewriting time.

A plurality of memory cells are arranged in m columns in FIG. 8. Therefore, data subjected to rewriting are concurrently rewritten by data supplied to the wiring WBL1[1] to the wiring WBL1[m]. That is, the semiconductor device with the configuration shown in this embodiment is regarded as a memory device having an m-bit data width (m bit/width) for a given address.

In the period from Time T20 to Time T28, the wiring RWL_D1 and the wiring RWL_D2 are supplied with “L”. The section interposed between the selection transistor DTr2[1] and the transistor DTr3[1] can be brought into a floating state, for example. Since a potential supplied to the wiring RBL1 and the wiring RBL2 does not affect the memory module, the wiring RBL1 and the wiring RBL2 can be brought into a floating state. Therefore, power supplied to the wiring RBL1 and the wiring RBL2 can be reduced. Alternatively, a given potential may be supplied to the wiring RBL1 and the wiring RBL2.

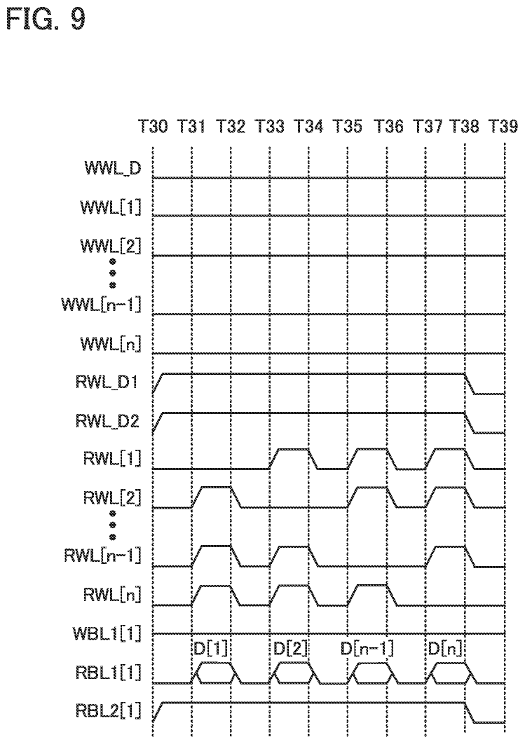

Next, operation for reading data that is written according to FIG. 7 will be described with reference to a timing chart in FIG. 9.

At Time T30, the wiring RBL1[1] to the wiring RBL1[m] can be initialized with a given potential. The wiring RBL2[1] to the wiring RBL2[m] are supplied with a reference potential for confirming that the memory cell stores given data. The given potential for initialization is preferably the same potential as “L” of data or a potential lower than “L” of data. In the period in which the wiring RBL2[1] to the wiring RBL2[m] are supplied with the reference potential, the wiring RWL_D1 and the wiring RWL_D2 are supplied with “H” and the selection transistor DTr2 and the selection transistor DTr3 are turned on.

At Time T31, data stored in the memory cell MC[1,1] to the memory cell MC[m,1] connected to the wiring RWL[1] can be read. The wiring RWL[1] is supplied with “L” and the other wirings RWL[2] to RWL[n] are supplied with “H”. Since the transistors RTr are connected in series, when “H” data is retained in any of the memory cell MC[1,1] to the memory cell MC[m,1], a signal with the reference potential is output to the wiring RBL1 in the row to which the memory cell MC retaining “H” data belongs.

When “H” is supplied from the wiring RWL[2] to the wiring RWL[n] to the memory cells MC connected to the wiring RWL[2] to the wiring RWL[n], the capacitor CS can make the gate of the transistor RTr in a state of being supplied with “H” according to the charge conservation law. Thus, among the transistors RTr connected in series, all the transistors RTr except the one subjected to reading are turned on. Accordingly, when data in the memory cell subjected to reading is “L”, the reference potential supplied to the wiring RBL2 cannot be output to the wiring RBL1. On the other hand, when data in the memory cell subjected to reading is “H”, the reference potential supplied to the wiring RBL2 is output to the wiring RBL1. As a result, data stored in the memory cell MC[1,1] to the memory cell MC[m,1] is output to the wiring RBL1[1] to the wiring RBL1[m].

At Time T32, the wiring RWL[1] to the wiring RWL[n] are supplied with “L”, and the wiring RBL1[1] to the wiring RBL1[m] are initialized with a given potential. At this time, the wiring RBL2[1] to the wiring RBL2[m] are preferably supplied with “H” but may be supplied with “L”.

At Time T33, data stored in the memory cell MC[1,2] to the memory cell MC[m,2] connected to the wiring RWL[2] can be read. The wiring RWL[2] is supplied with “L” and the other wirings RWL[1] and RWL[3] to RWL[n] are supplied with “H”. The subsequent operation is the same as the operation for reading data from the wiring RWL[1], and the description thereof is therefore omitted.

The operation at Time T34 is the same as that at Time T32, and the description thereof is therefore omitted. After Time T34 (in the period from Time T35 to Time T39), reading operation is performed on each row in a manner similar to the operation at Time T31 and Time T33, whereby the data stored in the memory cells MC connected to the wiring RWL[3] to the wiring RWL[n] can be read. As a result, data in the memory cells MC can be read sequentially in the row direction of the memory cells.

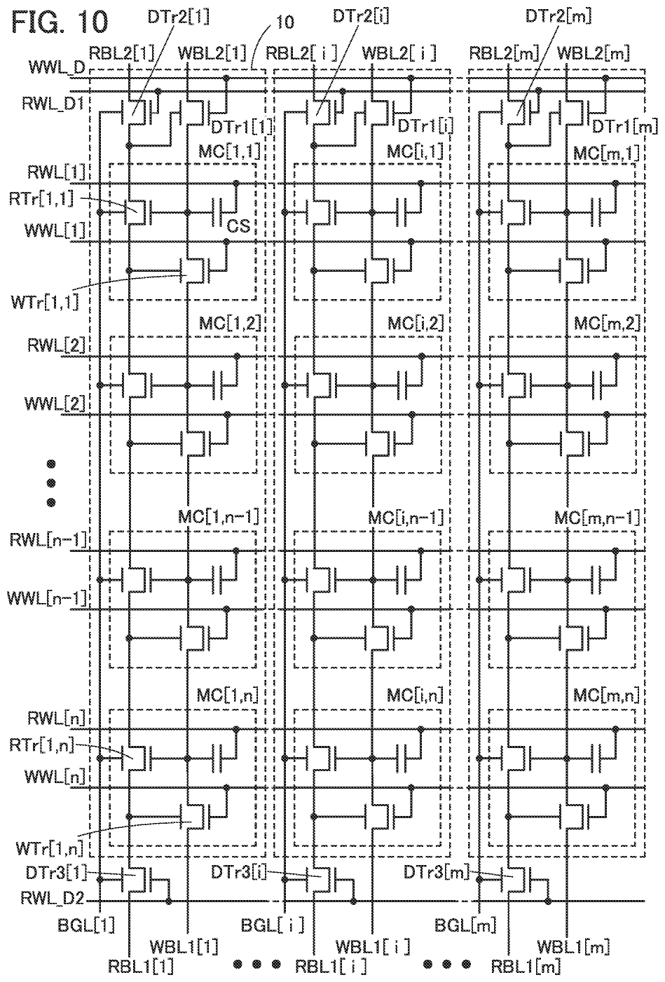

A semiconductor device different from that in FIG. 2 will be described with reference to FIG. 10. The semiconductor device illustrated in FIG. 10 is different from that in FIG. 2 in that one of the source and the drain of the selection transistor DTr1 is electrically connected to a wiring WBL2. For simplicity, the description is made using the memory module 10 as an example.

Since the wiring WBL2 is electrically connected to one of the source and the drain of the selection transistor DTr1, the memory module 10 can rewrite data in the memory cell MC from one or both of the wiring WBL1 and the wiring WBL2.

That is, by supply of “H” to the wiring WWL_D, the wiring WBL2[1] can rewrite data in the memory node of the memory cell MC[1,1] through the selection transistor DTr1[1]. By supply of “H” to the wiring WWL[n], the wiring WBL1[1] can rewrite data in the memory node of the memory cell MC[1,n]. Moreover, by simultaneous supply of “H” to the wiring WWL[1] and the wiring WWL[n], data in the memory nodes of the memory cell MC[1,1] and the memory cell MC[1,n] can be rewritten at the same time.

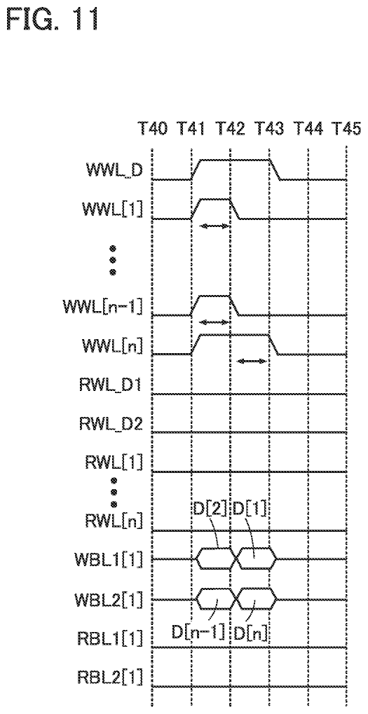

Operation for rewriting data in the first row, the second row, the (n−1)-th row, and the n-th row by a method different from that in FIG. 7 will be described with reference to a timing chart in FIG. 11.

At Time T40, the wiring WWL_D, the wiring WWL[1] to the wiring WWL[n], the wiring RWL_D1, the wiring RWL_D2, the wiring RWL[1] to the wiring RWL[n], the wiring RBL1[1], and the wiring RBL2[2] are supplied with “L”. Data is not input to the wiring WBL1[1] and the wiring WBL2[1].

At Time T41, the selection transistor DTr1 [1] to the selection transistor DTr1[m] are turned on by supply of “H” to the wiring WWL_D. The transistors WTr included in the memory cell MC[1,1] to the memory cell MC[m,1] are turned on by supply of “H” to the wiring WWL[1]. Thus, by the data D[2] supplied to the wiring WBL2[1] to the wiring WBL2[m], data in the memory cell MC[1,2] to the memory cell MC[m,2] can be rewritten through the selection transistor DTr1[1] to the selection transistor DTr1[m]. At this time, the data D[2] is also supplied to the memory cell MC[1,1] to the memory cell MC[m,1].

In addition, the transistors WTr included in the memory cell MC[1,n] to the memory cell MC[m,n] are turned on by supply of “H” to the wiring WWL[n]. The transistors WTr included in the memory cell MC[1,n−1] to the memory cell MC[m,n−1] are turned on by supply of “H” to the wiring WWL[n−1]. Thus, by the data D[n−1] supplied to the wiring WBL1[1] to the wiring WBL1[m], data in the memory nodes of the memory cell MC[1,n−1] to the memory cell MC[m,n−1] can be rewritten. At this time, the data D[n−1] is also supplied to the memory cell MC[1,n] to the memory cell MC[m,n].

Consequently, data in the memory nodes of the memory cell MC[1,2] to the memory cell MC[m,2] and the memory cell MC[1,n−1] to the memory cell MC[m,n−1] is rewritten at the same time.

At Time T42, the transistors WTr included in the memory cell MC[1,1] to the memory cell MC[m,1] are turned off by supply of “L” to the wiring WWL[1], and the transistors WTr included in the memory cell MC[1,n−1] to the memory cell MC[m,n−1] are turned off by supply of “L” to the wiring WWL[n−1]. Hence, the data D[2] is stored in the memory nodes of the memory cell MC[1,2] to the memory cell MC[m,2], and the data D[n−1] is stored in the memory nodes of the memory cell MC[1,n−1] to the memory cell MC[m,n−1].

By the data D[1] supplied to the wiring WBL2[1] to the wiring WBL2[m], the data in the memory cell MC[1,1] to the memory cell MC[m,1] can be rewritten through the selection transistor DTr1[1] to the selection transistor DTr1[m]. Moreover, by the data D[n] supplied to the wiring WBL2[1] to the wiring WBL2[m], the data in the memory cell MC[1,n] to the memory cell MC[m,n] can be rewritten through the selection transistor DTr1[1] to the selection transistor DTr1[m].

In FIG. 11, following the data rewriting, the wiring WWL_D and the wiring WWL[n] are supplied with “L” after Time T43 (in the period from Time T43 to Time T45).

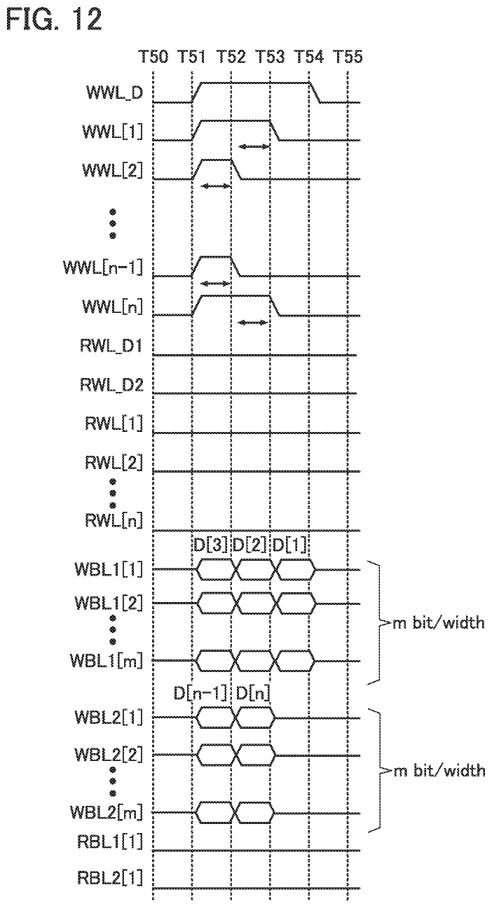

Using FIG. 12, the description is made on an example in which a plurality of memory modules included in the semiconductor device are connected through the wirings WWL, the wirings RWL, and the wiring WWL_D and data to be stored has an m-bit data width. As an example, operation for rewriting data in the first row, the second row, the third row, the (n−1)-th row, and the n-th row is described with reference to a timing chart in FIG. 12.

Basic operation is the same as the operation described with FIG. 11, and therefore the description thereof is not repeated; differences from FIG. 11 are described with FIG. 12. For example, at Time T51, data in the second row and data in the (n−1)-th row are rewritten at the same time. At Time T52, data in the first row and data in the n-th row are rewritten at the same time.

When two different rows, for example, are subjected to rewriting in the memory module having n rows, each of the two rows is preferably concurrently accessed through the closer one of the two memory cells MC: the first-row memory cell MC to which the selection transistor DTr1 is connected, and the n-th-row memory cell MC. Two different rows can be subjected to rewriting at the same time, so that the time for rewriting in the memory cells can be further shortened. Accordingly, access from the end closer to the given row subjected to rewriting leads to a shorter rewriting time.

A plurality of memory cells are arranged in m columns in FIG. 12. Therefore, data subjected to rewriting are concurrently rewritten by data supplied to the wiring WBL1[1] to the wiring WBL1[m] and data supplied to the wiring WBL2[1] to the wiring WBL2[m]. That is, the semiconductor device with the configuration shown in this embodiment is regarded as a memory device having an m-bit data width for a given address.

According to FIG. 10 to FIG. 12, data in given rows of the memory module can be concurrently rewritten from different directions, and thus data rewriting can be even faster than that with the circuit configuration described with reference to FIG. 2.

The structure and method described in this embodiment can be used by being combined as appropriate with the structures and methods described in the other embodiments.

### Embodiment 2

In this embodiment, a memory device including the semiconductor device described in the above embodiment will be described.

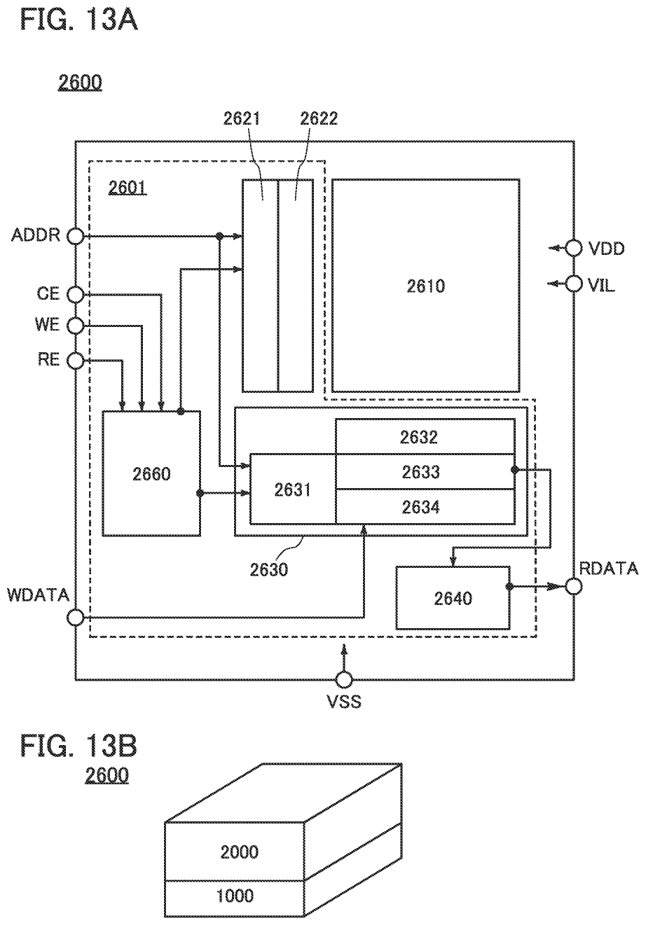

FIG. 13A shows a structure example of a memory device. A memory device 2600 includes a peripheral circuit 2601 and a memory cell array 2610. The peripheral circuit 2601 includes a row decoder 2621, a word line driver circuit 2622, a bit line driver circuit 2630, an output circuit 2640, and a control logic circuit 2660.

The semiconductor device that is described in Embodiment 1 and illustrated in FIG. 1A, FIG. 1B, or FIG. 1C can be used for the memory cell array 2610.

The bit line driver circuit 2630 includes a column decoder 2631, a precharge circuit 2632, a sense amplifier 2633, and a writing circuit 2634. The precharge circuit 2632 has a function of precharging the wirings RBL2 described in Embodiment 1 to a predetermined potential. The sense amplifier 2633 has a function of obtaining a potential output from the memory cell MC to the wiring RBL1 as a data signal and amplifying the data signal. The amplified data signal is output to the outside of the memory device 2600 as a digital data signal RDATA through the output circuit 2640.

As power supply potentials, a low power supply potential (VSS), a high power supply potential (VDD) for the peripheral circuit 2601, and a high power supply potential (VIL) for the memory cell array 2610 are supplied to the memory device 2600 from the outside.

Control signals (CE, WE, and RE), an address signal ADDR, and a data signal WDATA are input to the memory device 2600 from the outside. The address signal ADDR is input to the row decoder 2621 and the column decoder 2631, and the data signal WDATA is input to the write circuit 2634.

The control logic circuit 2660 processes the signals (CE, WE, and RE) input from the outside, and generates control signals for the row decoder 2621 and the column decoder 2631. CE is a chip enable signal, WE is a write enable signal, and RE is a read enable signal. Signals processed by the control logic circuit 2660 are not limited to those listed above, and other control signals may be input as necessary.

Note that whether each circuit or each signal described above is provided or not can be appropriately determined as needed.

FIG. 13B shows an example in which the memory device 2600 is configured with a p-channel Si transistor and a transistor whose channel formation region contains an oxide semiconductor (preferably an oxide containing In, Ga, and Zn). As an example, the memory device 2600 illustrated in FIG. 13B includes a logic layer 1000 where the peripheral circuit is constituted by Si transistors, and a memory layer 2000. That is, the memory layer 2000 formed with transistors that contain an oxide semiconductor in their channel formation regions is provided above the logic layer 1000.

Accordingly, providing the sense amplifier 2633 below the memory layer 2000 can shorten the wiring RBL1 that connects the sense amplifier 2633 and the memory cells MC. Thus, the wiring RBL1 is less affected by its time constant, so that the speed of reading data from the memory cell MC can be increased. The use of the transistor containing an oxide semiconductor for the memory cell MC results in lower off-state current of the memory cell MC. Data leakage between adjacent memory cells MC can be suppressed; hence, data can be retained for a long time. Moreover, the refresh interval for the memory cells can be lengthened, reducing power consumption of the memory device 2600. Furthermore, when the Si transistors are only p-channel ones, the manufacturing cost can be reduced. Alternatively, only n-channel Si transistors may be employed.

FIG. 14 to FIG. 16 illustrate configurations of the memory cell array 2610 in FIG. 13. For clarity of the drawing, some components are not shown in FIG. 14 to FIG. 16.

In FIG. 14, the wiring RBL1[m], the wiring WBL1[m], a wiring WWL[n,d], and a wiring RWL[n,d] are connected to the memory cell MC[m,n,d]. That is, the semiconductor device illustrated in FIG. 14 includes the memory cell MC[1,1,1] to the memory cell MC[m,n,d] that are arranged in three dimensions with the depth direction.

FIG. 14 also includes the selection transistor DTr1, the selection transistor DTr2, the selection transistor DTr3, the wiring WWL_D, the wiring RWL_D1, and the wiring RWL_D2. One end and the other end of the memory module 10 are connected to the wiring WBL1 through the selection transistor DTr1, the one end of the memory module 10 is connected to the wiring RBL2 through the selection transistor DTr2, and the other end of the memory module 10 is connected to the wiring RBL1 through the selection transistor DTr3. The wiring WWL_D is electrically connected to the gate of the selection transistor DTr1, the wiring RWL_D1 is electrically connected to the gate of the selection transistor DTr2, and the wiring RWL_D2 is electrically connected to the gate of the selection transistor DTr3.

The selection transistor DTr2 can precharge the memory module 10 with a predetermined potential used for data reading. Note that the wiring RBL2 may be fixed at a given high potential. The selection transistor DTr3 can select the memory module 10 to be subjected to data reading. The wiring RWL_D2 through which data is read can individually turn off the selection transistors DTr3 connected to unselected memory modules 10.

Thus, the unselected memory module 10 can be isolated, resulting in higher signal quality of data that is read from the selected memory cell to the wiring RBL1. The selection transistor DTr3 is preferably provided particularly when data retained in the memory module 10 is analog data. As another example, the selection transistor DTr2 can be controlled to read data through the wiring RBL2. Note that the selection transistor DTr2 or the selection transistor DTr3 can be provided as needed.

The wiring RBL1 and the wiring WBL1 are preferably provided every column in the depth direction d and connected to a bit line driver circuit 2630A. Similarly, the wiring RBL2 is preferably provided every column in the depth direction d and electrically connected to a bit line driver circuit 2630B. Thus, the memory cell MC[1,1] to the memory cell MC[m,n] are treated as a unit of data access. That is, the data width is m bits. The semiconductor device of this embodiment can be easily used for not only a general memory but also a frame memory of a display device.

Shortening the wirings WBL1 can reduce variations of the memory modules 10 due to wiring resistance; thus, the data rewriting time can be shortened.

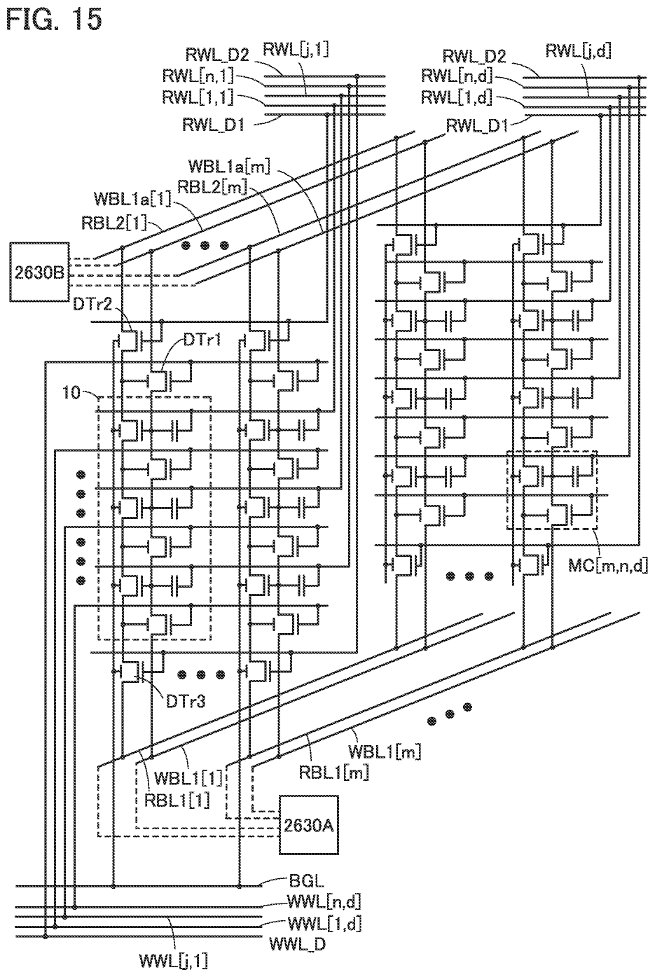

FIG. 15 illustrates a configuration of the memory cell array 2610 different from that in FIG. 14. In FIG. 15, wirings WBL1a are further provided, and the wirings WBL1a are electrically connected to the memory modules 10 through the selection transistors DTr1. In FIG. 14, the wirings WBL1 are electrically connected in the vicinity of the memory modules 10 and shared by the memory modules 10, and the memory modules 10 are electrically connected to the bit line driver circuit 2630A. FIG. 15 shows an example in which the memory module 10 is electrically connected to the bit line driver circuit 2630A through the wiring WBL1 and is electrically connected to the bit line driver circuit 2630B through the wiring WBL1a. The wirings WBL1 and the wirings WBL1a illustrated in FIG. 15 are preferably electrically connected to the bit line driver circuit 2630A and the bit line driver circuit 2630B, respectively, outside the memory cell array 2610. Note that the bit line driver circuit 2630A and the bit line driver circuit 2630B preferably function as one bit line driver circuit 2630. Thus, since the wirings WBL1 do not need to be connected in the vicinity of the memory modules 10 in the memory cell array 2610 illustrated in FIG. 15, the data density of the semiconductor device can be increased.

FIG. 15 illustrates a configuration of the memory cell array 2610 different from that in FIG. 14. In FIG. 15, the wirings WBL1a are further provided, and the wirings WBL1a are electrically connected to the memory modules 10 through the selection transistors DTr1. In FIG. 14, the wirings WBL1 are electrically connected in the vicinity of the memory modules 10 and shared by the memory modules 10, and the memory modules 10 are electrically connected to the bit line driver circuit 2630A. FIG. 15 shows an example in which the memory module 10 is connected to the bit line driver circuit 2630A through the wiring WBL1 or the wiring WBL2. The wirings WBL1 or the wirings WBL2 illustrated in FIG. 15 are preferably connected to the bit line driver circuit 2630A outside the memory cell array 2610. With such a configuration, the memory cell array 2610 can increase the data density of the semiconductor device, compared to the case using the configuration illustrated in FIG. 14.

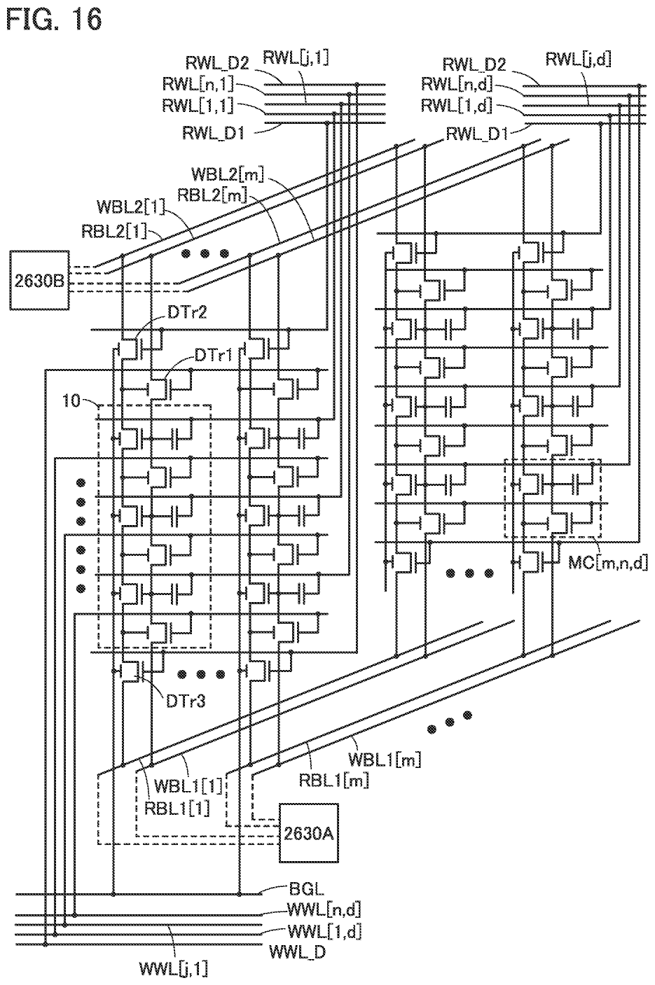

Furthermore, in FIG. 16, one end of the memory module 10 is connected to the wiring WBL2 through the selection transistor DTr1. The wiring WBL1 and the wiring RBL1 are connected to the bit line driver circuit 2630A, and the wiring WBL2 and the wiring RBL2 are connected to the bit line driver circuit 2630B. Accordingly, data in the memory module 10 can be rewritten with a signal supplied from the bit line driver circuit 2630A to the wiring WBL1 and a signal supplied from the bit line driver circuit 2630B to the wiring WBL2. As described with reference to FIG. 12, rewriting or reading operation can be performed on the same memory module 10 from the bit line driver circuit 2630A and the bit line driver circuit 2630B at the same time.

### STRUCTURE EXAMPLE AND MANUFACTURING METHOD EXAMPLE

For easy understanding of the structure of the semiconductor device in this embodiment, a method for manufacturing the semiconductor device will be described below.

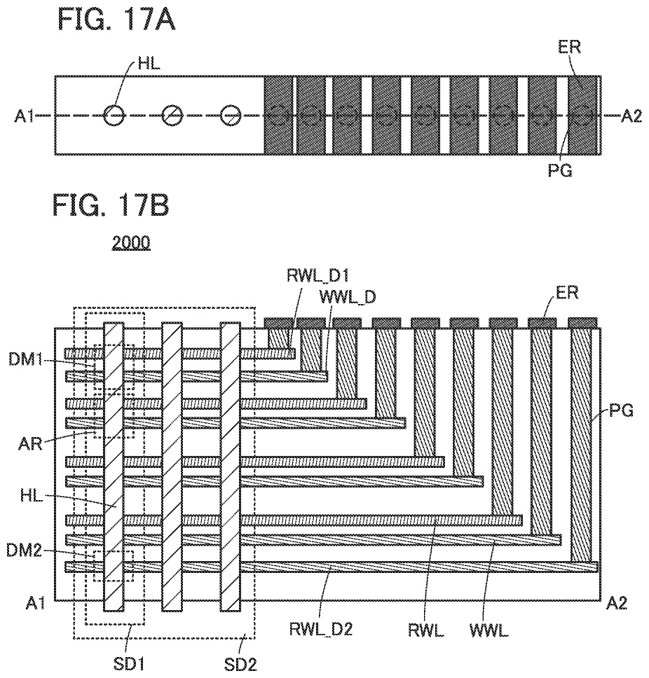

FIG. 17A and FIG. 17B are schematic views illustrating the semiconductor device illustrated in FIG. 1A to FIG. 1C. FIG. 17A is a top view of the semiconductor device, and FIG. 17B is a cross-sectional view along the dashed-dotted line A1-A2 in FIG. 17A.

The semiconductor device includes a structure body in which the wirings RWL, the wirings WWL, and insulators (regions without a hatching pattern in FIG. 17A and FIG. 17B) are stacked; openings are provided in the structure body, and conductors PG are formed to fill the openings. A wiring ER is formed over the conductor PG, so that the wiring ER is electrically connected to the wiring WWL_D, the wiring RWL_D1, the wiring RWL_D2, the wiring RWL, or the wiring WWL.

In addition, openings are formed in the structure body to penetrate the wirings RWL and the wirings WWL altogether. In the opening, the selection transistor DTr1 and the selection transistor DTr2 can be provided in a region DM1, the transistor WTr and the transistor RTr included in the memory cell MC can be provided in a region AR, and the selection transistor DTr3 can be provided in a region DM2; the regions penetrate the wiring WWL_D, the wirings RWL, and the wiring WWL. Therefore, an insulator, a conductor, and a semiconductor for forming the transistor are formed in the opening. The conductor functions as the wiring WBL or the wiring RBL, and the semiconductor functions as the channel formation region of the selection transistor DTr1, the selection transistor DTr2, the selection transistor DTr3, the transistor WTr, or the transistor RTr.

The region where the insulator, the conductor, and the semiconductor are formed in the opening is shown as a region HL in FIG. 17. When the transistor includes a back gate, the conductor included in the region HL functions as the back gate. Therefore, the back gate can be referred to as the wiring BGL.

In other words, FIG. 17 shows that the semiconductor device illustrated in FIG. 1A or FIG. 1B is formed in a region SD1, and the semiconductor device illustrated in FIG. 2 or FIG. 10 is formed in a region SD2.

A method for forming the transistor included in the memory cell MC formed in the region AR will be described in Manufacturing method example 1 and Manufacturing method example 2 below.

### Manufacturing Method Example 1

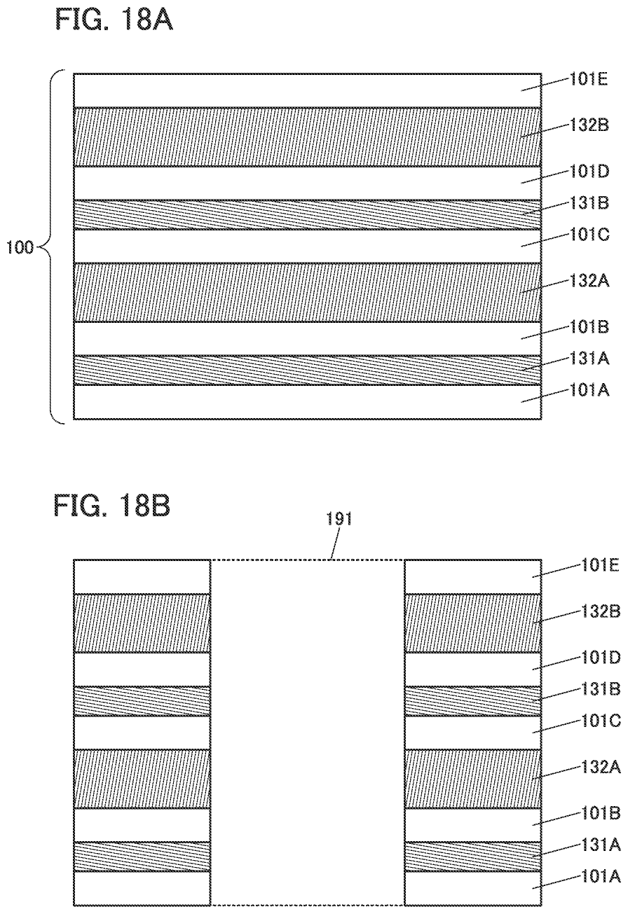

FIG. 18 to FIG. 22 are cross-sectional views for describing an example of manufacturing the semiconductor device illustrated in FIG. 1A, and are specifically cross-sectional views of the transistor WTr and the transistor RTr in the channel length direction. For simplification of the drawing, some components are not shown in the cross-sectional views in FIG. 18 to FIG. 22.

As illustrated in FIG. 18A, the semiconductor device in FIG. 1A includes an insulator 101A placed over a substrate (not shown), a conductor 131A placed over the insulator 101A, an insulator 101B placed over the conductor 131A, a conductor 132A placed over the insulator 101B, an insulator 101C placed over the conductor 132A, a conductor 131B placed over the insulator 101C, an insulator 101D placed over the conductor 131B, a conductor 132B placed over the insulator 101D, and an insulator 101E placed over the conductor 132B. Note that a stack including the plurality of conductors and the plurality of insulators is hereinafter referred to as a stack 100.

Note that as the substrate, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. In addition, a semiconductor substrate in which an insulator region is included in the above semiconductor substrate, e.g., an SOI (Silicon On Insulator) substrate and the like are given. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a transistor, a switching element, a light-emitting element, and a memory element.

A flexible substrate may be used as the substrate. As an example of a method for providing a transistor over a flexible substrate, there is also a method in which the transistor is manufactured over a non-flexible substrate and then the transistor is separated and transferred to a flexible substrate. In that case, a separation layer is preferably provided between the non-flexible substrate and the transistor. As the substrate, a sheet, a film, a foil, or the like in which a fiber is weaved may be used. In addition, the substrate may have elasticity. Furthermore, the substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact applied to a semiconductor device over the substrate, which is caused by dropping or the like, can be reduced, for example. That is, a durable semiconductor device can be provided.

For the flexible substrate, metal, an alloy, a resin, glass, or fiber thereof can be used, for example. The flexible substrate preferably has a lower coefficient of linear expansion because deformation due to an environment is inhibited. For the flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (e.g., nylon and aramid), polyimide, polycarbonate, and acrylic. In particular, aramid is preferable for the flexible substrate because of its low coefficient of linear expansion.

In the manufacture example described in this embodiment, heat treatment is included in the process; therefore, a material having high heat resistance and a low coefficient of thermal expansion is preferably used for the substrate.

The conductor 131A (the conductor 131B) functions as the wiring WWL illustrated in FIG. 1A, and the conductor 132A (the conductor 132B) functions as the wiring RWL illustrated in FIG. 1A.

For the conductor 131A, the conductor 131B, the conductor 132A, and the conductor 132B, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For the above conductors, especially for the conductor 131A and the conductor 131B, a conductive material containing oxygen and a metal element included in a metal oxide usable for a semiconductor 1, a semiconductor 152, a semiconductor 153a, and a semiconductor 153b that are described later may be used. Alternatively, a conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. Using such a material in some cases allows capture of hydrogen entering from a surrounding insulator or the like.

Moreover, a conductive material having a function of inhibiting transmission of impurities such as water or hydrogen is preferably used for the above conductors, especially for the conductor 132A and the conductor 132B. For example, tantalum, tantalum nitride, titanium, titanium nitride, ruthenium, or ruthenium oxide is preferably used, and a single layer or a stacked layer can be used.

A plurality of conductors formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed. When an insulator including an excess-oxygen region is used as the insulator in contact with the conductor, oxygen is in some cases diffused into a region of the conductor in contact with the insulator. Accordingly, a stacked-layer structure combining a material containing the metal element and a conductive material containing oxygen can be formed. Similarly, when an insulator including an excess-nitrogen region is used as the insulator in contact with the conductor, nitrogen is in some cases diffused into a region of the conductor in contact with the insulator. Accordingly, a stacked-layer structure combining a material containing the metal element and a conductive material containing nitrogen can be formed.

The conductor 131A, the conductor 131B, the conductor 132A, and the conductor 132B may use the same material or different materials. That is, materials used for the conductor 131A, the conductor 131B, the conductor 132A, and the conductor 132B included in the semiconductor device of one embodiment of the present invention can be selected as appropriate.

The insulator 101A to the insulator 101E preferably use materials in which the concentration of impurities such as water or hydrogen is reduced. The amount of hydrogen released from the insulator 101A to the insulator 101E, which is converted into hydrogen molecules per area of one of the insulator 101A to the insulator 101E, is less than or equal to 2×10¹⁵ molecules/cm², preferably less than or equal to 1×10¹⁵ molecules/cm², further preferably less than or equal to 5×10¹⁴ molecules/cm² in thermal desorption spectroscopy (TDS) in a film-surface temperature range of 50° C. to 500° C., for example. The insulator 101A to the insulator 101E may be formed using an insulator from which oxygen is released by heating. In that case, the conductor 131A, the conductor 131B, the conductor 132A, and the conductor 132B can have a stacked-layer structure using a combination of a material containing the metal element and a conductive material containing oxygen, as described above.

The insulator 101A to the insulator 101E can be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. For example, a material containing silicon oxide or silicon oxynitride can be used.

Note that in this specification, silicon oxynitride refers to a material that contains oxygen at a higher proportion than nitrogen, and silicon nitride oxide refers to a material that contains nitrogen at a higher proportion than oxygen. Furthermore, in this specification, aluminum oxynitride refers to a material that contains oxygen at a higher proportion than nitrogen, and aluminum nitride oxide refers to a material that contains nitrogen at a higher proportion than oxygen.

In the next step, as illustrated in FIG. 18B, an opening 191 is formed in the stack 100 illustrated in FIG. 18A through resist mask formation and etching treatment, or the like.

The formation of the resist mask can be performed by a lithography method, a printing method, an inkjet method, or the like as appropriate. Formation of the resist mask by an inkjet method needs no photomask; thus, fabrication cost can be reduced. For the etching treatment, either a dry etching method or a wet etching method or both of them may be used.

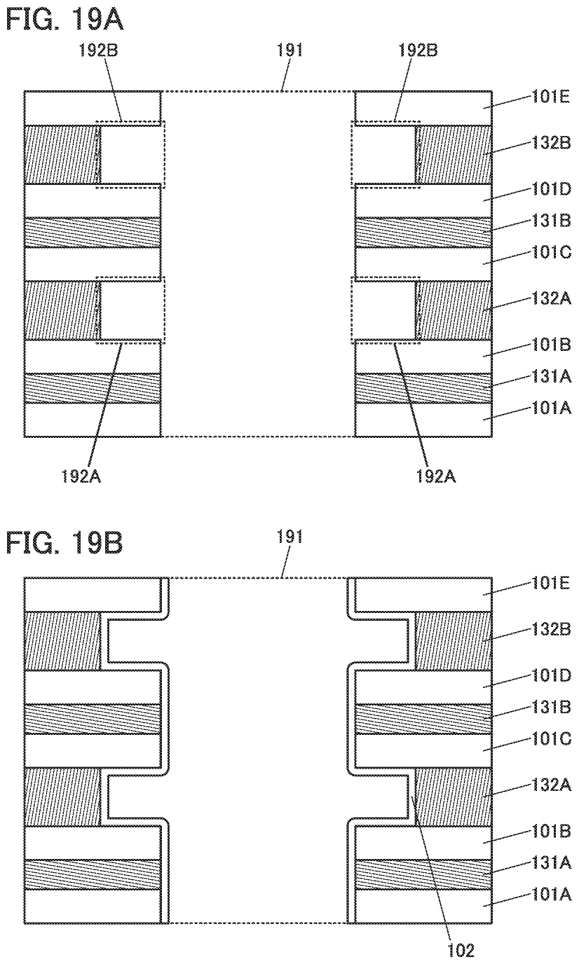

Then, as illustrated in FIG. 19A, the conductor 132A (the conductor 132B) on a side surface of the opening 191 is removed by etching treatment or the like, and a recess portion 192A (a recess portion 192B) is formed on the side surface. Here, a material for the conductor 132A (the conductor 132B) is selected such that the conductor 132A (the conductor 132B) is selectively removed in the stack 100, i.e., such that the conductor 132A (the conductor 132B) has a higher etching rate than the insulator 101A to the insulator 101E and the conductor 131A (the conductor 131B).

Alternatively, the recess portion 192A (the recess portion 192B) may be formed as follows: in the step of manufacturing the semiconductor device illustrated in FIG. 18A, a sacrificial layer is provided in a region where the opening 191 and the recess portion 192A (the recess portion 192B) are to be formed, and then the opening 191 and the recess portion 192A (the recess portion 192B) are formed together in the step of manufacturing the semiconductor device illustrated in FIG. 18B. Alternatively, the recess portion 192A (the recess portion 192B) can be formed by itself when the opening 191 is formed without a sacrificial layer.

In the next step, as illustrated in FIG. 19B, an insulator 102 is deposited on the side surface of the opening 191 illustrated in FIG. 19A and in the recess portions.

An insulating material having a function of inhibiting transmission of oxygen is preferably used for the insulator 102. For the insulator 102, silicon nitride, silicon nitride oxide, silicon oxynitride, aluminum nitride, or aluminum nitride oxide is preferably used, for example. The formation of such an insulator 102 can prevent a reduction in conductivity of a conductor 133 described later due to oxidation of the conductor 133 caused when oxygen enters the conductor 133 through the insulator 102.

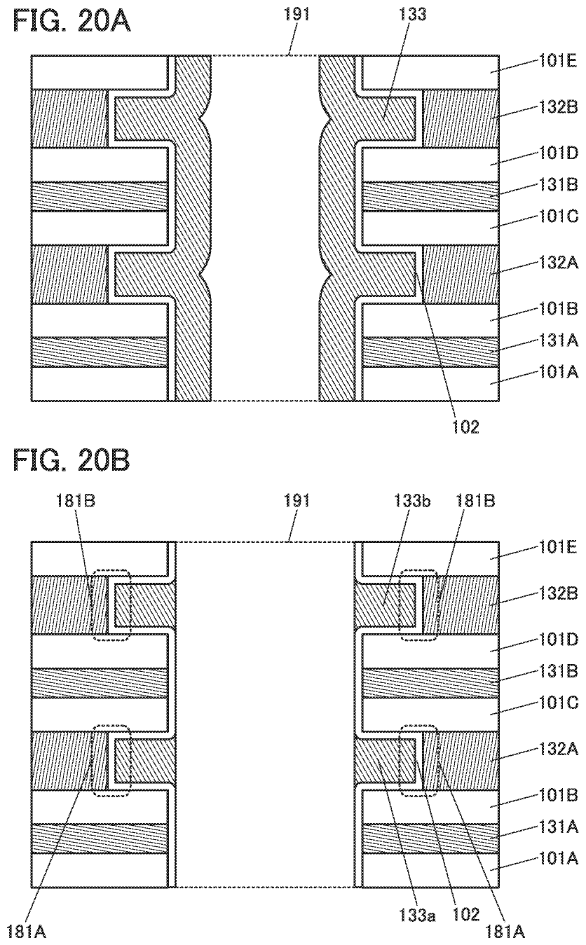

In the next step, as illustrated in FIG. 20A, the conductor 133 is deposited on the side surface of the opening 191 and in the formed recess portions illustrated in FIG. 19B. That is, the conductor 133 is formed on the insulator 102.

For the conductor 133, any of the above materials usable for the conductor 131A, the conductor 131B, the conductor 132A, and the conductor 132B can be used. In particular, a material with high conductivity among the above materials is preferably used for the conductor 133.

In the next step, as illustrated in FIG. 20B, the conductor 133 included in the opening 191 is removed by resist mask formation and etching treatment, or the like so that the conductor 133 remains only in the aforementioned recess portions. Thus, a conductor 133a and a conductor 133b are formed. Note that at this time, part of the insulator 102 may be removed as long as the insulator 101A to the insulator 101E, the conductor 131A, and the conductor 131B are not exposed at the opening 191.

Note that the description of FIG. 18B is referred to for the resist mask formation and the etching treatment.

The conductor 133a (the conductor 133b) functions as the other electrode of the capacitor CS illustrated in FIG. 1A. That is, the capacitor CS is formed in the region 181A (the region 181B) illustrated in FIG. 20B.

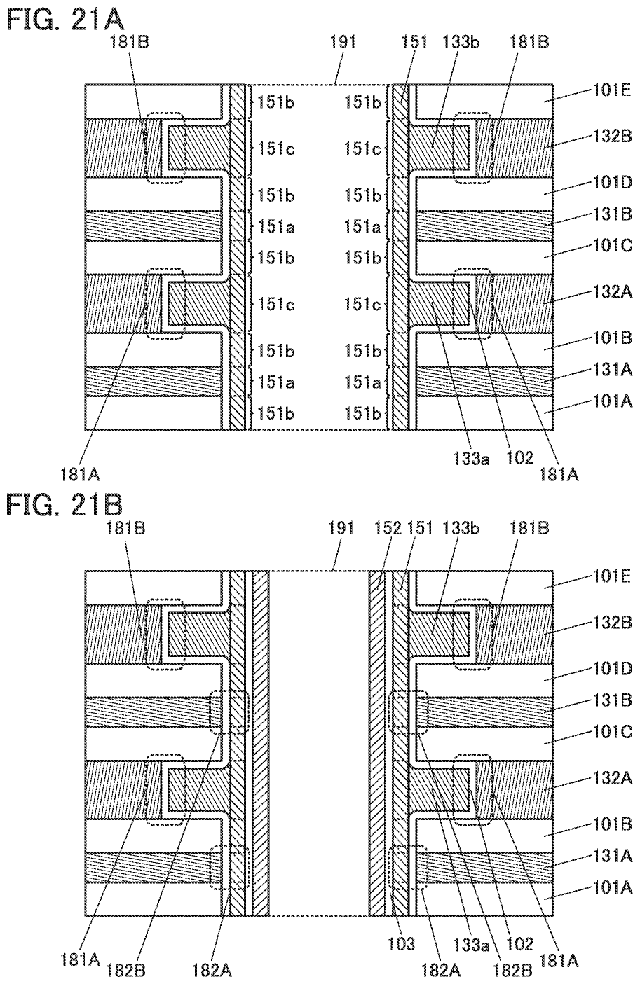

In the next step, as illustrated in FIG. 21A, a semiconductor 151 is deposited on the insulator 102, the conductor 133a, and the conductor 133b that are positioned on the side surface of the opening 191.

For the semiconductor 151, a material containing one or more metal oxides selected from indium, an element M (M is aluminum, gallium, yttrium, or tin, for example), and zinc is preferably used.

When the semiconductor 151 contains a metal oxide, for the insulator 102 in contact with the semiconductor 151, it is preferable to use an insulating material having a function of inhibiting the passage of impurities such as water or hydrogen as well as oxygen. The formation of such an insulator 102 can prevent impurities such as water or hydrogen from entering the semiconductor 151 through the insulator 102 and becoming water by reaction with oxygen contained in the semiconductor 151. If water is produced in the semiconductor 151, an oxygen vacancy may be formed in the semiconductor 151. When an impurity such as hydrogen enters the oxygen vacancy, an electron serving as a carrier is generated in some cases. Consequently, if the semiconductor 151 has a region containing a large amount of hydrogen, a transistor including the region in its channel formation region is likely to have normally-on characteristics. To prevent this, for the insulator 102, it is preferable to use an insulating material having a function of inhibiting the passage of impurities such as water or hydrogen as well as oxygen.

The conductivity of the semiconductor 151 containing a metal oxide may vary depending on regions where the semiconductor 151 is formed. In FIG. 21A, among the regions where the semiconductor 151 is formed, regions in contact with the insulator 102 are illustrated as a region 151a and a region 151b, and a region in contact with the conductor 133a (the conductor 133b) is illustrated as a region 151c. Specifically, the region 151a overlaps with the side surface of the conductor 131A (the conductor 131B), and the region 151b overlaps with the side surface of the insulator 101A (the insulator 101B to the insulator 101E). Since the region 151c is in contact with the conductor 133a (the conductor 133b), impurities such as hydrogen or water contained in the conductor 133a (the conductor 133b) may be diffused into the region 151c. As described above, an electron serving as a carrier may be generated when impurities such as water or hydrogen are diffused into the semiconductor 151; hence, the resistance of the region 151c may be lowered. For that reason, the region 151c has higher conductivity than the region 151a and the region 151b.

The region 151a serves as a channel formation region of the transistor. Thus, the resistance of the region 151a is lowered when the transistor is on; therefore, the region 151a has higher conductivity than the region 151b.

In the next step, as illustrated in FIG. 21B, an insulator 103 and the semiconductor 152 are sequentially deposited on the semiconductor 151 on the side surface of the opening 191.

Any of the above materials usable for the insulator 102 can be used for the insulator 103. Particularly when the semiconductor 151 contains a metal oxide, for the insulator 103, it is preferable to use an insulating material having a function of inhibiting the passage of impurities such as water or hydrogen as well as oxygen.

In a region 182A (a region 182B) illustrated in FIG. 21B, the transistor WTr illustrated in FIG. 1A is formed. Specifically, in the region 182A (the region 182B), the region 151a of the semiconductor 151 functions as the channel formation region of the transistor WTr, two regions 151b of the semiconductor 151 function as the source electrode and the drain electrode of the transistor WTr, and the conductor 132A functions as the gate electrode of the transistor WTr. In particular, when a material containing a metal oxide is used for the semiconductor 151, the transistor WTr is an oxide semiconductor (OS) transistor.

As for the semiconductor 151, a material containing one or more metal oxides selected from indium, an element M (M is aluminum, gallium, yttrium, or tin, for example), and zinc can be used for the semiconductor 152. Moreover, the semiconductor 152 can be replaced with a semiconductor material such as polycrystalline silicon or amorphous silicon.

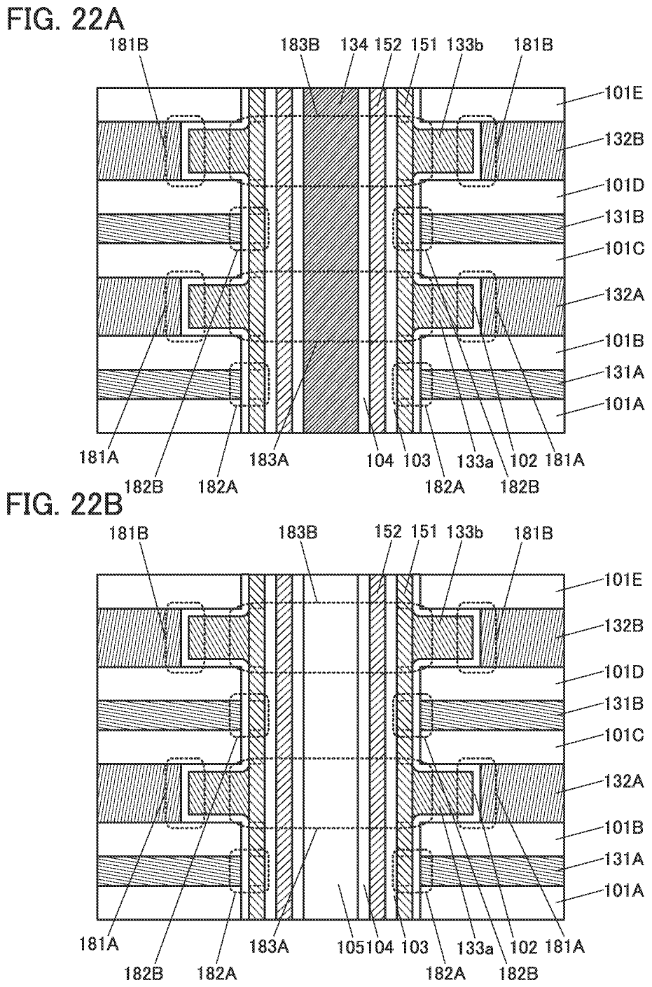

In the next step, as illustrated in FIG. 22A, an insulator 104 is deposited on the semiconductor 152, and a conductor 134 is deposited to fill the remaining opening 191.

Any of the above materials usable for the insulator 102 and the insulator 103 can be used for the insulator 104.

For the conductor 134, any of the materials usable for the conductor 131A, the conductor 131B, the conductor 132A, the conductor 132B, the conductor 133a, and the conductor 133b can be used.

In a region 183A (a region 183B) illustrated in FIG. 22A, the transistor RTr illustrated in FIG. 1A is formed. Specifically, in the region 183A (the region 183B), the region 151c and two regions 151b of the semiconductor 151 and the conductor 133a (the conductor 133b) function as the gate electrode of the transistor RTr, the semiconductor 152 functions as the channel formation region of the transistor RTr, and the conductor 134 functions as a back gate electrode of the transistor RTr. In particular, when a material containing a metal oxide is used for the semiconductor 152, the transistor RTr is an OS transistor.

The semiconductor device illustrated in FIG. 1A can be manufactured through the steps from FIG. 18A to FIG. 22A.

One embodiment of the present invention is not limited to the structure example of the semiconductor device illustrated in FIG. 22A. One embodiment of the present invention can have a structure which is changed as appropriate from that of the semiconductor device illustrated in FIG. 22A depending on the case, according to circumstances, or as needed.

For example, as described above, one embodiment of the present invention can also be a semiconductor device in which the transistor WTr and the transistor RTr do not include a back gate as illustrated in FIG. 1C. In the case of manufacturing the semiconductor device illustrated in FIG. 1C, the step illustrated in FIG. 22B is performed instead of the step illustrated in FIG. 22A in the process of manufacturing the semiconductor device illustrated in FIG. 1A. Specifically, FIG. 22B illustrates, for example, a step for depositing an insulator 105, instead of the conductor 134 in FIG. 22A, to fill the opening 191. Any of the above materials usable for the insulator 104 can be used for the insulator 105, for example.

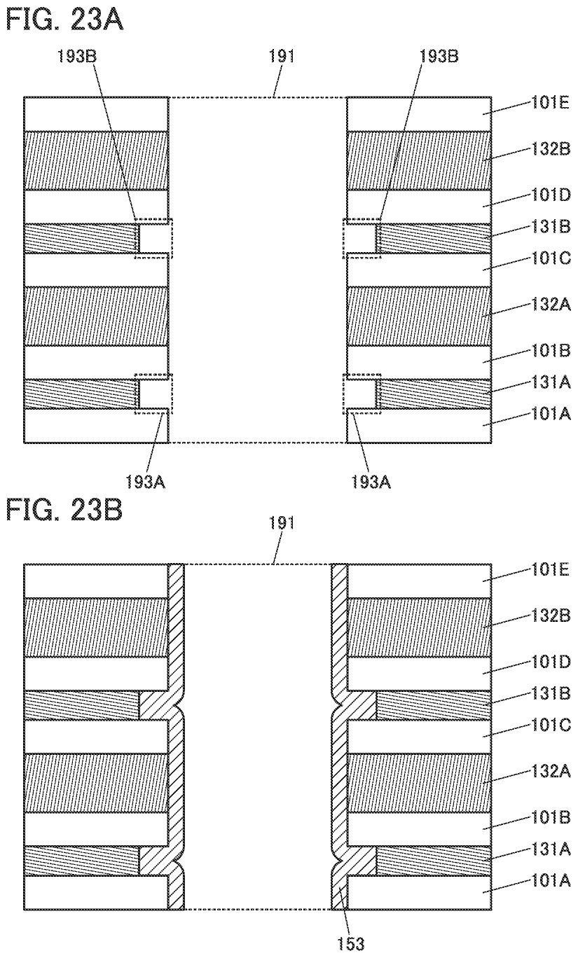

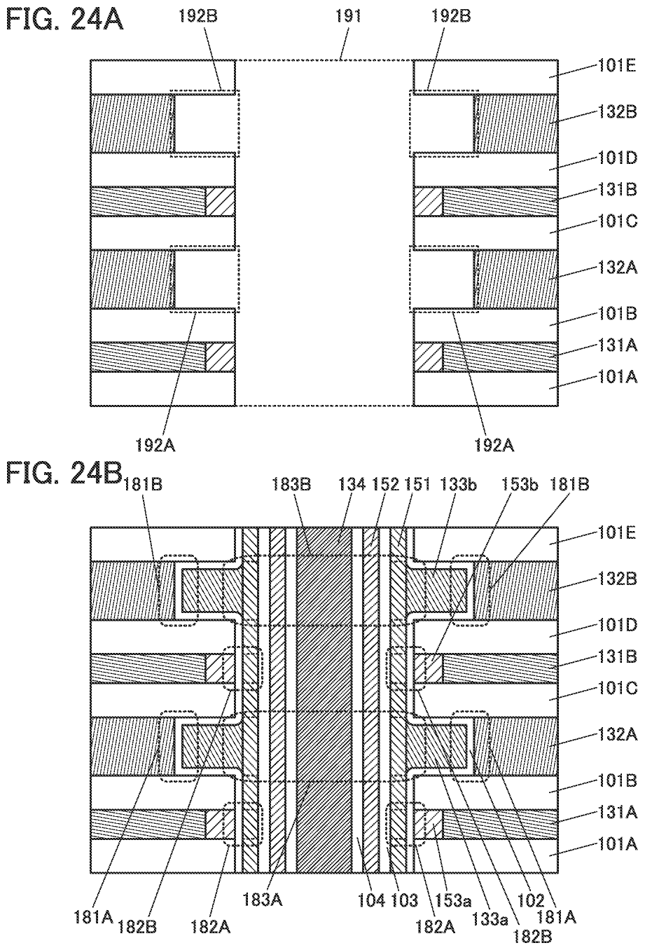

For example, in one embodiment of the present invention, the structure of the gate electrode of the transistor WTr may be changed from the structure illustrated in FIG. 22A in order to improve the switching characteristics of the transistor WTr. FIG. 23A, FIG. 23B, FIG. 24A, and FIG. 24B show an example of a method for manufacturing the semiconductor device. FIG. 23A illustrates a step of removing the conductor 131A (the conductor 131B) on the side surface of the opening 191 in FIG. 18B and forming a recess portion 193A (a recess portion 193B). Here, a material for the conductor 131A (the conductor 131B) is selected such that the conductor 131A (the conductor 131B) is selectively removed in the stack 100, i.e., such that the conductor 131A (the conductor 131B) has a higher etching rate than the conductor 132A (the conductor 132B) and the insulator 101A to the insulator 101E.

Alternatively, the recess portion 193A (the recess portion 193B) may be formed as follows: in the step of manufacturing the semiconductor device illustrated in FIG. 18A, a sacrificial layer is provided in a region where the opening 191 and the recess portion 193A (the recess portion 193B) are to be formed, and then the opening 191 and the recess portion 193A (the recess portion 193B) are formed together in the step of manufacturing the semiconductor device illustrated in FIG. 18B. Alternatively, the recess portion 193A (the recess portion 193B) can be formed by itself when the opening 191 is formed without a sacrificial layer.

In the next step, as illustrated in FIG. 23B, the semiconductor 153 is deposited on the side surface of the opening 191 illustrated in FIG. 23A and in the recess portion 193A (the recess portion 193B).

For the semiconductor 153, a material containing one or more metal oxides selected from indium, an element M (M is aluminum, gallium, yttrium, or tin, for example), and zinc is preferably used.

In the next step, as illustrated in FIG. 24A, the semiconductor 153 included in the opening 191 is removed by resist mask formation and etching treatment, or the like so that only the semiconductor 153 in the recess portion 193A (the recess portion 193B) remains, and the semiconductor 153a (the semiconductor 153b) is formed. At the same time as this process or after this process, etching treatment is performed so that the conductor 132A (the conductor 132B) is removed to form the recess portion 192A (the recess portion 192B).

Next, as in the step of FIG. 20B, the insulator 102 is formed on the side surface of the opening 191 so as to cover the semiconductor 153a (the semiconductor 153b). When a material containing a metal oxide is used for the semiconductor 153a (the semiconductor 153b), by the contact between the semiconductor 153a (the semiconductor 153b) and the insulator 102, impurities such as hydrogen or water contained in the insulator 102 are diffused into the semiconductor 153a (the semiconductor 153b). In addition, since the semiconductor 153a (the semiconductor 153b) is in contact with the conductor 133a (the conductor 133b), impurities such as hydrogen or water contained in the conductor 133a (the conductor 133b) are sometimes diffused into the semiconductor 153a (the semiconductor 153b). That is, the semiconductor 153a (the semiconductor 153b) has a function of capturing impurities such as hydrogen or water. Thus, the resistance of the semiconductor 153a (the semiconductor 153b) is reduced, and the semiconductor 153a (the semiconductor 153b) can function as the gate electrode of the transistor WTr. Subsequently, steps similar to those in from FIG. 21A to FIG. 22A are performed, whereby a semiconductor device illustrated in FIG. 24B can be constituted.

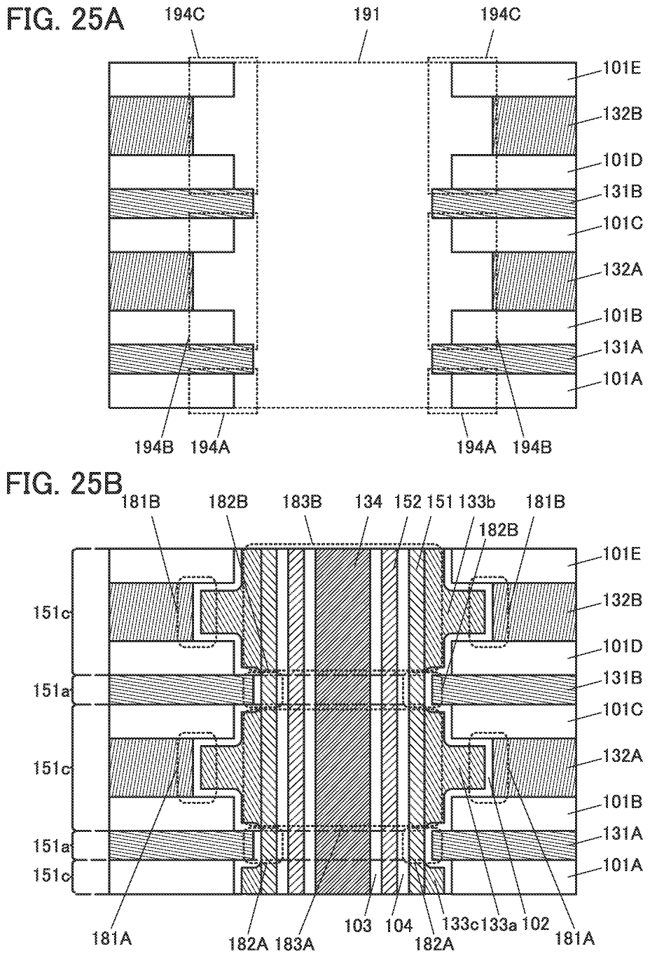

As another example, in one embodiment of the present invention, the structure of the gate electrode of the transistor RTr can be changed from the structure illustrated in FIG. 22A in order to reduce the electrical resistance between the gate of the transistor RTr and the first terminal or the second terminal of the transistor WTr illustrated in FIG. 1A. FIG. 25A and FIG. 25B show an example of a method for manufacturing such a semiconductor device. FIG. 25A illustrates a step of removing the insulator 101A to the insulator 101E as well as the conductor 132A (the conductor 132B) on the side surface of the opening 191 in FIG. 19A and forming a recess portion 194B (a recess portion 194A and a recess portion 194C). Here, materials for the conductor 132A (the conductor 132B) and the insulator 101A to the insulator 101E are selected such that the conductor 132A (the conductor 132B) and the insulator 101A to the insulator 101E are selectively removed in the stack 100, i.e., such that the conductor 132A (the conductor 132B) and the insulator 101A to the insulator 101E have a higher etching rate than the conductor 131A (the conductor 131B).

Alternatively, the recess portion 194B (the recess portion 194A and the recess portion 194C) may be formed as follows: in the step of manufacturing the semiconductor device illustrated in FIG. 18A, a sacrificial layer is provided in a region where the opening 191 and the recess portion 194B (the recess portion 194A and the recess portion 194C) are to be formed, and then the opening 191 and the recess portion 194B (the recess portion 194A and the recess portion 194C) are formed together in the step of manufacturing the semiconductor device illustrated in FIG. 18B. Alternatively, the recess portion 194B (the recess portion 194A and the recess portion 194C) can be formed by itself when the opening 191 is formed without a sacrificial layer.

In FIG. 25A, in the recess portion 194B (the recess portion 194A and the recess portion 194C), the conductor 132A (the conductor 132B) is removed deeper than the insulator 101B and the insulator 101C (the insulator 101A, the insulator 101D, and the insulator 101E); alternatively, the insulator 101B and the insulator 101C (the insulator 101A, the insulator 101D, and the insulator 101E) may be removed deeper than the conductor 132A (the conductor 132B). Moreover, the insulator 101B and the insulator 101C (the insulator 101A, the insulator 101D, and the insulator 101E) and the conductor 132A (the conductor 132B) may be formed to have the same depth.

FIG. 25B shows a structure example of the semiconductor device manufactured through the step in FIG. 25A. After the step in FIG. 25A, the conductor 133 is deposited so as to fill the recess portion 194B (the recess portion 194A and the recess portion 194C), whereby the gate electrode of the transistor RTr is formed. FIG. 25B illustrates the conductor 133a, the conductor 133b, and a conductor 133c that function as the gate electrode of the transistor RTr. Subsequently, steps similar to those in from FIG. 21A to FIG. 22A are performed, whereby a semiconductor device illustrated in FIG. 25B can be constituted. In this semiconductor device, the contact area between the semiconductor 151 and the conductor 133a (the conductor 133b) is larger than that in the semiconductor device illustrated in FIG. 22A. When a material containing a metal oxide is used for the semiconductor 151 in the semiconductor device illustrated in FIG. 25B, the electrical resistance between the first terminal or the second terminal of the transistor WTr and the gate of the transistor RTr can be reduced because the region 151b illustrated in FIG. 22A does not exist.

### Manufacturing Method Example 2

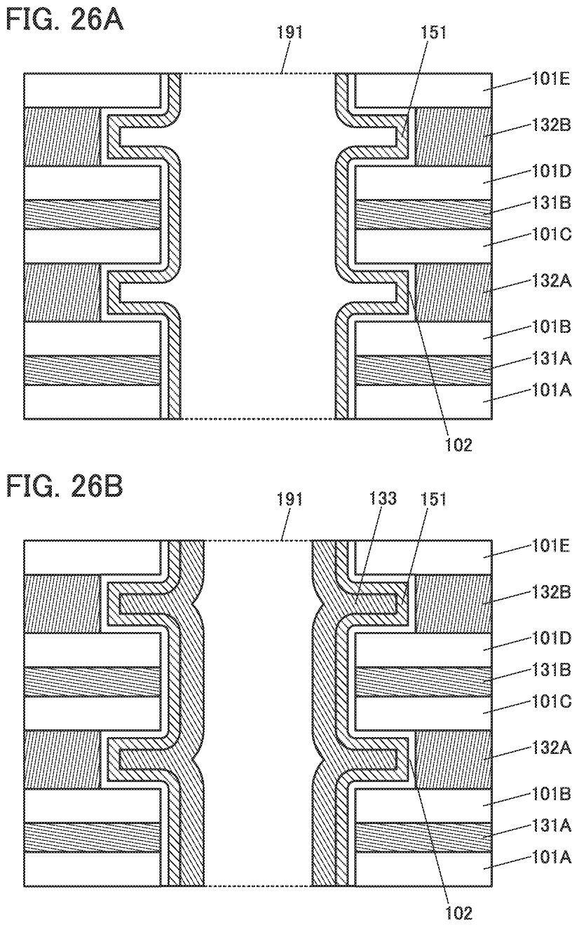

Here, a structure example of the semiconductor device in this embodiment that is different from that in Manufacturing method example 1 will be described with reference to FIG. 26 to FIG. 28.

Like FIG. 18 to FIG. 22, FIG. 26 to FIG. 28 are cross-sectional views for describing an example of manufacturing the semiconductor device illustrated in FIG. 1A, and show specifically cross-sectional views of the transistor WTr and the transistor RTr in the channel length direction. For simplification of the drawing, some components are not shown in the cross-sectional views in FIG. 26 to FIG. 28, as in FIG. 18 to FIG. 22.

The description of FIG. 18A to FIG. 19B made in Manufacturing method example 1 is referred to for the beginning steps.

A step illustrated in FIG. 26A is subsequent to the step illustrated in FIG. 19B. In FIG. 26A, the semiconductor 151 is deposited on the side surface of the opening 191 and in the formed recess portions illustrated in FIG. 19B. That is, the semiconductor 151 is formed on the insulator 102.

For the semiconductor 151, a material containing one or more semiconductors selected from indium, an element M (M is aluminum, gallium, yttrium, or tin, for example), and zinc is preferably used.

In the next step, as illustrated in FIG. 26B, the conductor 133 is deposited on the side surface of the opening 191 and in the formed recess portions illustrated in FIG. 26A.

The description of the conductor 133 made in Manufacturing method example 1 is referred to for the conductor 133.

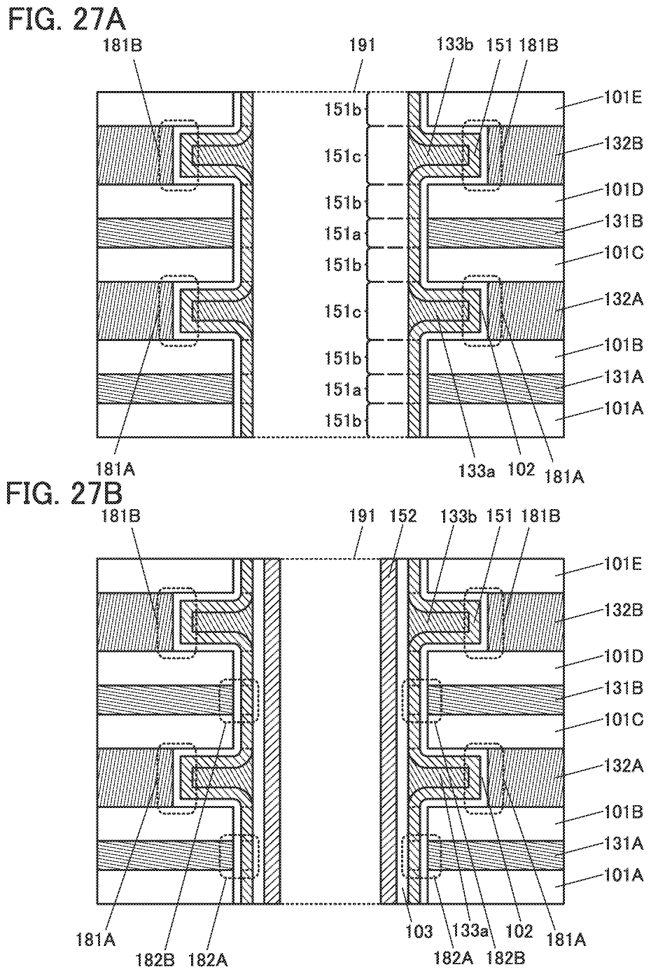

In the next step, as illustrated in FIG. 27A, the conductor 133 included in the opening 191 is removed by resist mask formation and etching treatment, or the like so that the conductor 133 remains only in the aforementioned recess portions. Thus, the conductor 133a and the conductor 133b are formed. Note that at this time, part of the semiconductor 151 may be removed as long as the insulator 102 is not exposed at the opening 191.

Note that the description of FIG. 18B is referred to for the resist mask formation and the etching treatment.

The conductor 133a (the conductor 133b) functions as the other electrode of the capacitor CS illustrated in FIG. 1A. That is, the capacitor CS is formed in the region 181A (the region 181B) illustrated in FIG. 27A.

The description of the semiconductor 151 made in Manufacturing method example 1 is referred to for the semiconductor 151. When the semiconductor 151 contains a metal oxide, the semiconductor 151 can be divided into the region 151a, the region 151b, and the region 151c. The description of the region 151a, the region 151b, and the region 151c made in Manufacturing method example 1 is referred to for the region 151a, the region 151b, and the region 151c.

In the next step, as illustrated in FIG. 27B, the insulator 103 is deposited on the conductor 133a, the conductor 133b, and the semiconductor 151 on the side surface of the opening 191, and then the semiconductor 152 is deposited on the insulator 103.

The description of the insulator 103 made in Manufacturing method example 1 is referred to for the insulator 103.

The description of the semiconductor 152 made in Manufacturing method example 1 is referred to for the semiconductor 152.

In the region 182A (the region 182B) illustrated in FIG. 27B, the transistor WTr illustrated in FIG. 1A is formed. Specifically, in the region 182A (the region 182B), the region 151a of the semiconductor 151 functions as the channel formation region of the transistor WTr, two regions 151b of the semiconductor 151 function as the source electrode and the drain electrode of the transistor WTr, and the conductor 132A functions as the gate electrode of the transistor WTr. In particular, when a material containing a metal oxide is used for the semiconductor 151, the transistor WTr is an OS transistor.

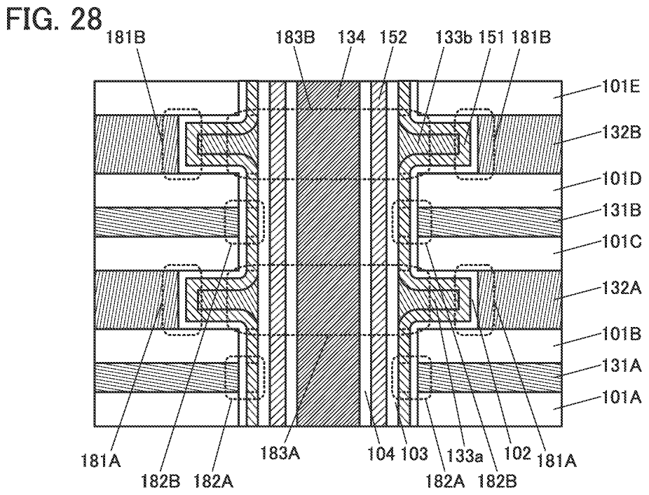

In the next step, as illustrated in FIG. 28, the insulator 104 is deposited on the semiconductor 152, and the conductor 134 is deposited to fill the remaining opening 191.

The description of the insulator 104 made in Manufacturing method example 1 is referred to for the insulator 104.

The description of the conductor 134 made in Manufacturing method example 1 is referred to for the conductor 134.

In the region 183A (the region 183B) illustrated in FIG. 28, the transistor RTr illustrated in FIG. 1A is formed. Specifically, in the region 183A (the region 183B), the region 151c and two regions 151b of the semiconductor 151 and the conductor 133a (the conductor 133b) function as the gate electrode of the transistor RTr, the semiconductor 152 functions as the channel formation region of the transistor RTr, and the conductor 134 functions as the back gate electrode of the transistor RTr. In particular, when a material containing a metal oxide is used for the semiconductor 152, the transistor RTr is an OS transistor.

The semiconductor device illustrated in FIG. 1A can be manufactured through the steps from FIG. 18A to FIG. 19B and from FIG. 26A to FIG. 28.

One embodiment of the present invention is not limited to the structure example of the semiconductor device illustrated in FIG. 28. One embodiment of the present invention can have a structure which is changed as appropriate from that of the semiconductor device illustrated in FIG. 28 depending on the case, according to circumstances, or as needed.

For example, as described above, one embodiment of the present invention can also be a semiconductor device in which the transistor WTr and the transistor RTr do not include a back gate as illustrated in FIG. 1C. In the case of manufacturing the semiconductor device illustrated in FIG. 1C, deposition of the insulator 105 is performed to fill the opening 191 as in the step illustrated in FIG. 22B instead of the step illustrated in FIG. 28 in the process of manufacturing the semiconductor device illustrated in FIG. 1A (not illustrated). Any of the above materials usable for the insulator 104 can be used for the insulator 105, for example.

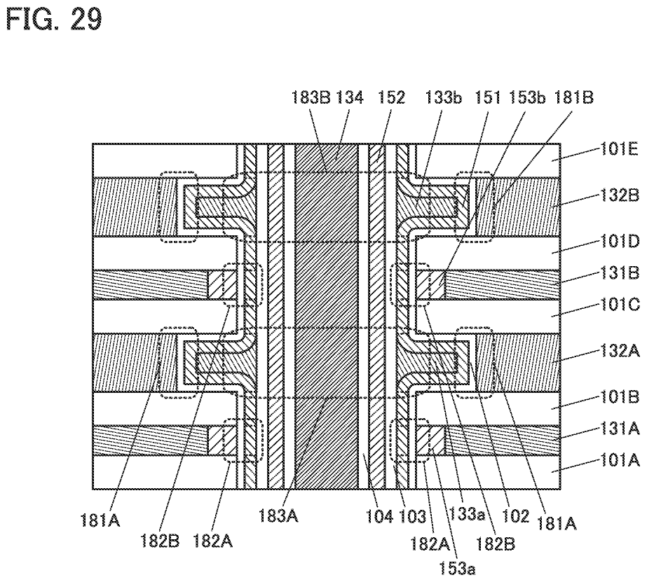

For example, in one embodiment of the present invention, the structure of the gate electrode of the transistor WTr may be changed from the structure illustrated in FIG. 28 in order to improve the switching characteristics of the transistor WTr. FIG. 29 shows a structure example of the semiconductor device. To manufacture the semiconductor device illustrated in FIG. 29, the semiconductor 153a (the semiconductor 153b) is formed so as to fill the recess portion 193A (the recess portion 193B) as in the structure example that is shown in FIG. 24B and described in Manufacturing method example 1. Next, the insulator 102 is formed on the side surface of the opening 191 so as to cover the semiconductor 153a (the semiconductor 153b). Subsequently, steps similar to those in from FIG. 26A to FIG. 28 are performed, whereby a semiconductor device illustrated in FIG. 29 can be constituted. Note that the description for FIG. 23A, FIG. 23B, FIG. 24A, and FIG. 24B made in Manufacturing method example 1 is referred to for the effects of constituting FIG. 29.

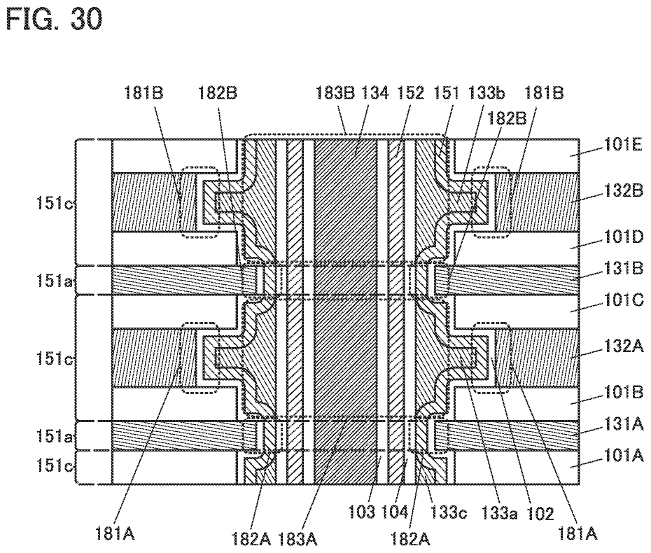

As another example, in one embodiment of the present invention, the structure of the gate electrode of the transistor RTr can be changed from the structure illustrated in FIG. 28 in order to reduce the electrical resistance between the gate of the transistor RTr and the first terminal or the second terminal of the transistor WTr illustrated in FIG. 1A. FIG. 30 shows a structure example of the semiconductor device. To manufacture the semiconductor device illustrated in FIG. 30, the structure example that is shown in FIG. 25A and described in Manufacturing method example 1 is manufactured. Subsequently, steps similar to those in from FIG. 26A to FIG. 28 are performed, whereby a semiconductor device illustrated in FIG. 30 can be constituted. Note that the description of FIG. 25B made in Manufacturing method example 1 is referred to for the effects of constituting FIG. 30.

According to Manufacturing method example 1 or Manufacturing method example 2 described above, a semiconductor device capable of retaining a large amount of data can be manufactured.

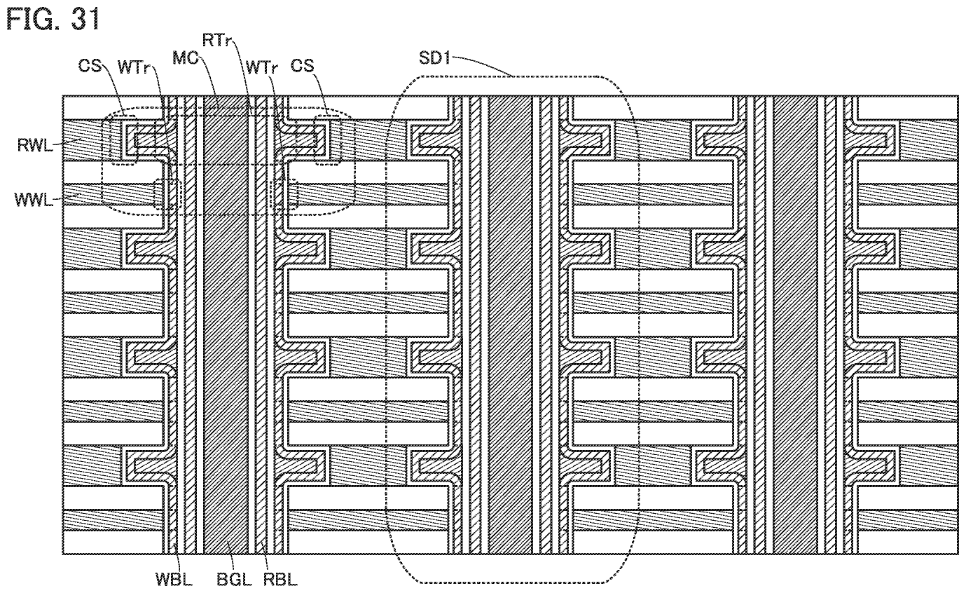

Here, FIG. 31 illustrates a structure in which the region SD2 of the semiconductor device illustrated in FIG. 17B employs the cross-sectional view of the semiconductor device illustrated in FIG. 22A (having the circuit configuration in FIG. 1A). Note that the region SD1 corresponds to the memory cells MC. As illustrated in FIG. 31, an opening is provided at a time to penetrate a structure body in which the conductors serving as the wirings RWL and the wirings WWL and the insulators are stacked, and the manufacturing process is performed according to the description in Manufacturing method example 1 and Manufacturing method example 2 described above, whereby the circuit configuration in FIG. 1A can be achieved.

<Connection Examples with Peripheral Circuit>

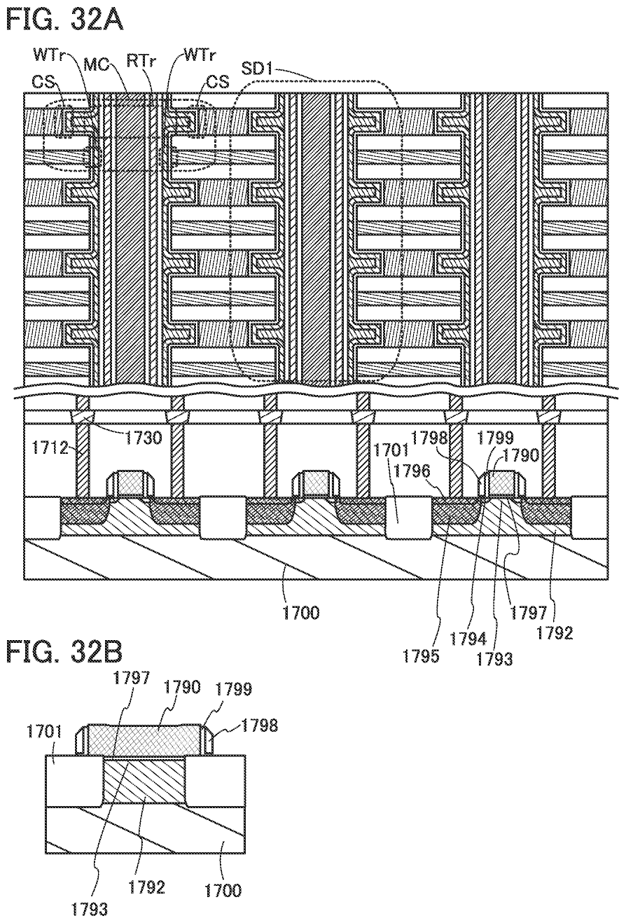

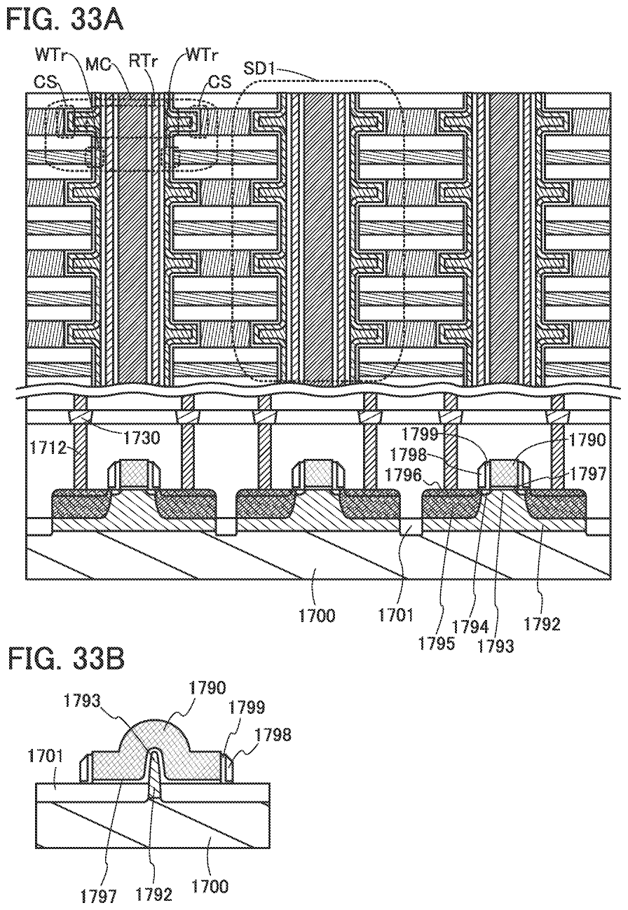

A peripheral circuit for the memory cell array, such as a read circuit or a precharge circuit, may be provided below the semiconductor device shown in Manufacturing method example 1 or Manufacturing method example 2. In this case, Si transistors are formed over a silicon substrate or the like to configure the peripheral circuit, and then the semiconductor device of one embodiment of the present invention is formed over the peripheral circuit according to Manufacturing method example 1 or Manufacturing method example 2. FIG. 32A is a cross-sectional view in which the peripheral circuit is configured with planar Si transistors and the semiconductor device of one embodiment of the present invention is formed thereover. FIG. 33A is a cross-sectional view in which the peripheral circuit is configured with FIN Si transistors and the semiconductor device of one embodiment of the present invention is formed thereover. As an example, the semiconductor devices illustrated in FIG. 32A and FIG. 33A each have the structure in FIG. 22A.

In FIG. 32A and FIG. 33A, the Si transistors configuring the peripheral circuit are formed on a substrate 1700. An element isolation layer 1701 is formed between a plurality of Si transistors. Conductors 1712 are formed as a source and a drain of the Si transistor. A conductor 1730 is formed with extension in the channel width direction and connected to another Si transistor or the conductor 1712 (not illustrated).

As the substrate 1700, a single crystal semiconductor substrate or a polycrystalline semiconductor substrate of silicon or silicon carbide, a compound semiconductor substrate of silicon germanium, an SOI substrate, or the like can be used.

Moreover, a glass substrate, a quartz substrate, a plastic substrate, a metal substrate, a flexible substrate, an attachment film, paper containing a fibrous material, or a base film, for example, may be used as the substrate 1700. After a semiconductor element is formed using one substrate, the semiconductor element may be transferred to another substrate. As an example, FIG. 32A and FIG. 33A show examples in which a single crystal silicon wafer is used as the substrate 1700.

Here, the details of the Si transistors are described. FIG. 32A is a cross-sectional view of the planar Si transistor in the channel length direction, and FIG. 32B is a cross-sectional view of the planar Si transistor in the channel width direction. The Si transistor includes a channel formation region 1793 provided in a well 1792, low-concentration impurity regions 1794 and high-concentration impurity regions 1795 (also collectively referred to simply as impurity regions), conductive regions 1796 provided in contact with the impurity regions, a gate insulating film 1797 provided over the channel formation region 1793, a gate electrode 1790 provided over the gate insulating film 1797, and sidewall insulating layers 1798 and sidewall insulating layers 1799 provided on side surfaces of the gate electrode 1790. Note that for the conductive regions 1796, a metal silicide or the like may be used.

FIG. 33A is a cross-sectional view of the FIN Si transistor in the channel length direction, and FIG. 33B is a cross-sectional view of the FIN Si transistor in the channel width direction. In the Si transistor illustrated in FIG. 33A and FIG. 33B, the channel formation region 1793 has a projecting portion, and the gate insulating film 1797 and the gate electrode 1790 are provided along its side surface and top surface. Although the case where the projecting portion is formed by processing part of the semiconductor substrate is described in this embodiment, a semiconductor layer with a projecting shape may be formed by processing an SOI substrate. Note that the reference numerals in FIG. 33A and FIG. 33B are the same as the reference numerals in FIG. 32A and FIG. 32B.

Note that the insulators, the conductors, the semiconductors, and the like disclosed in this specification and the like can be formed by a PVD (Physical Vapor Deposition) method or a CVD (Chemical Vapor Deposition) method. Examples of a PVD method include a sputtering method, a resistance heating evaporation method, an electron beam evaporation method, and a PLD (Pulsed Laser Deposition) method. A plasma CVD method, a thermal CVD method, or the like can be given as a CVD method. In particular, examples of a thermal CVD method include a MOCVD (Metal Organic Chemical Vapor Deposition) method and an ALD (Atomic Layer Deposition) method.

A thermal CVD method, which is a deposition method not using plasma, has an advantage that no defect due to plasma damage is generated.

Deposition by a thermal CVD method may be performed in such a manner that a source gas and an oxidizer are supplied to a chamber at a time, the pressure in the chamber is set to an atmospheric pressure or a reduced pressure, and they are made to react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (argon, nitrogen, or the like) or the like is introduced at the same time as or after the introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to form a first thin layer; then the second source gas is introduced to react with the first thin layer; as a result, a second thin layer is stacked over the first thin layer, so that a thin film is formed. The sequence of the gas introduction is controlled and repeated a plurality of times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and is thus suitable for manufacturing a minute FET.

A variety of films such as the metal film, the semiconductor film, and the inorganic insulating film disclosed in the above-described embodiment can be formed by a thermal CVD method such as a MOCVD method or an ALD method; for example, in the case of forming an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium and diethylzinc (Zn(C₂H₅)₂) can also be used instead of dimethylzinc.

For example, in the case where a hafnium oxide film is formed by a deposition apparatus using ALD, two kinds of gases, ozone (O₃) as an oxidizer and a source gas which is obtained by vaporizing liquid containing a solvent and a hafnium precursor compound (hafnium alkoxide or hafnium amide such as tetrakis(dimethylamide)hafnium (TDMAH, Hf[N(CH₃)₂]₄)), are used. Furthermore, examples of another material include tetrakis(ethylmethylamide)hafnium.

For example, in the case where an aluminum oxide film is formed by a deposition apparatus using ALD, two kinds of gases, H₂O as an oxidizer and a source gas which is obtained by vaporizing liquid containing a solvent and an aluminum precursor compound (trimethylaluminum (TMA, Al(CH₃)₃) or the like) are used. Furthermore, examples of another material include tris(dimethylamide)aluminum, triisobutylaluminum, and aluminum tris(2,2,6,6-tetramethyl-3,5-heptanedionate).

For example, in the case where a silicon oxide film is formed by a deposition apparatus using ALD, hexachlorodisilane is adsorbed on a surface on which a film is to be formed, and radicals of an oxidizing gas (O₂ or dinitrogen monoxide) are supplied to react with the adsorbate.

For example, in the case where a tungsten film is deposited by a deposition apparatus using ALD, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

For example, in the case where an oxide semiconductor film, for example, an In—Ga—Zn—O film, is deposited by a deposition apparatus using ALD, an In(CH₃)₃ gas and an O₃ gas are sequentially and repeatedly introduced to form an In—O layer, a Ga(CH₃)₃ gas and an O₃ gas are sequentially and repeatedly introduced to form a GaO layer, and then a Zn(CH₃)₂ gas and an O₃ gas are sequentially and repeatedly introduced to form a ZnO layer. Note that the order of these layers is not limited to this example. A mixed oxide layer such as an In—Ga—O layer, an In—Zn—O layer, or a Ga—Zn—O layer may be formed by using these gases. Note that although an H₂O gas which is obtained by bubbling water with an inert gas such as Ar may be used instead of an O₃ gas, it is preferable to use an O₃ gas, which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, a Zn(CH₃)₂ gas may be used.

Note that the structure examples of the semiconductor devices described in this embodiment can be combined with each other as appropriate.

Note that this embodiment can be combined with any of the other embodiments in this specification as appropriate.

### Embodiment 3

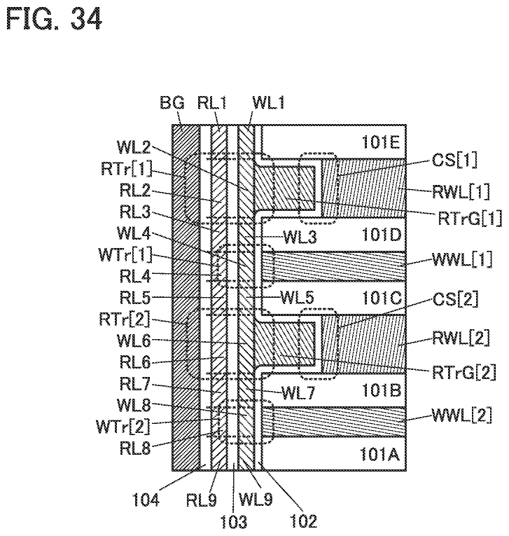

In this embodiment, a method for driving the semiconductor device of the above embodiment will be described in detail with reference to FIG. 34 to FIG. 40. FIG. 34 to FIG. 40 illustrate the semiconductor device described in Embodiment 2 (part of the cross-sectional view in FIG. 22A), and the method for driving the semiconductor device will be described with reference to these drawings. Note that in the structures of the invention described below, the same portions or portions having similar functions are denoted by the same reference numerals in different drawings, and description thereof is not repeated. Furthermore, Embodiment 1 can be referred to for the method for driving the semiconductor device. Note that in this embodiment, the semiconductor device is described as a memory module.

FIG. 34 is a diagram illustrating a memory module. The memory module includes a first memory cell, a second memory cell, a wiring BG, a wiring WL, a wiring RL, the wiring WWL[1], the wiring WVVL[2], the wiring RWL[1], and the wiring RWL[2], for example. The wiring WL and the wiring RL are semiconductor layers each containing a metal oxide. The wiring WL includes a region WL1 to a region WL9, and the wiring RL includes a region RL1 to a region RL9. Note that although FIG. 34 shows an example in which the memory module includes the first memory cell and the second memory cell, the number of memory cells that can be included in the memory module is not limited.

The first memory cell includes the transistor RTr[1] for reading, the transistor WTr[1] for rewriting, and the capacitor CS[1]. The second memory cell includes the transistor RTr[2] for reading, the transistor WTr[2] for rewriting, and a capacitor CS[2].

A gate electrode RTrG[1] of the transistor RTr[1] is in a position overlapping with the region WL2 and the region RL2. The wiring WWL[1] functioning as the gate electrode of the transistor WTr[1] is in a position overlapping with the region WL4 and the region RL4. Similarly, a gate electrode RTrG[2] of the transistor RTr[2] is in a position overlapping with the region WL6 and the region RL6. The wiring WWL[2] functioning as the gate electrode of the transistor WTr[2] is in a position overlapping with the region WL8 and the region RL8.

The capacitor CS[1] is formed when the gate electrode RTrG[1] of the transistor RTr[1] is placed in a position overlapping with the wiring RWL[1] with the insulator 102 therebetween. Thus, the gate electrode RTrG[1] can be referred to as a first memory node of the first memory cell. Data to be retained in the first memory node is retained in the capacitor CS[1].

The capacitor CS[2] is formed when the gate electrode RTrG[2] of the transistor RTr[2] is placed in a position overlapping with the wiring RWL[2] with the insulator 102 therebetween. Thus, the gate electrode RTrG[2] can be referred to as a second memory node of the second memory cell. Data to be retained in the second memory node is retained in the capacitor CS[2].

The wiring BG has a region overlapping with the wiring RL with the insulator 104 therebetween, and the wiring RL has a region overlapping with the wiring WL with the insulator 103 therebetween. The wiring BG is placed inward from the wiring RL with the insulator 104 therebetween, and the wiring RL is placed inward from the wiring WL with the insulator 103 therebetween.

The wiring BG includes a region functioning as the back gate of the transistor RTr[1], for example. The wiring BG can make the region RL1, the region RL3, the region RL4, the region RL5, the region RL7, the region RL8, and the region RL9 included in the wiring RL function as conductors.

The region RL2 functions as the channel formation region of the transistor RTr[1], and the region RL6 functions as the channel formation region of the transistor RTr[2]. The region RL4 functions as the back gate of the transistor WTr[1], and the region RL8 functions as a back gate of the transistor WTr[2].

When the region RL1, the region RL3, the region RL5, the region RL7, and the region RL9 are supplied with a potential, the region WL1, the region WL3, the region WL5, the region WL7, and the region WL9 can function as conductors. As another method, the resistance values of the region RL1, the region RL3, the region RL5, the region RL7, and the region RL9 are reduced by impurities such as hydrogen diffused from the insulator 101 (the insulator 101A to the insulator 101E), whereby the regions can be made to function as conductors.

Then, electrical connection in the memory module is described. Note that FIG. 1A can be referred to for the components of the memory module that are not illustrated in FIG. 34, such as the wiring WBL1, the wiring RBL1, the wiring RBL2, the wiring WWL_D, the wiring RWL_D1, the wiring RWL_D2, the selection transistor DTr1, the selection transistor DTr2, and the selection transistor DTr3.

First, the wiring WL is described. One of the source and the drain of the selection transistor DTr1 is electrically connected to the wiring WBL1. The gate of the selection transistor DTr1 is electrically connected to the wiring WWL_D.

The other of the source and the drain of the selection transistor DTr1 is electrically connected to the gate electrode RTrG[1] functioning as the first memory node through the region WL1. The region WL1 is preferably electrically connected to the gate electrode RTrG[1] through the region WL2. The gate electrode RTrG[1] is electrically connected to the region WL4 functioning as the channel formation region of the transistor WTr[1] through the region WL3. The gate electrode RTrG[1] is preferably electrically connected to the region WL3 through the region WL2.

The region WL4 is electrically connected to the gate electrode RTrG[2] functioning as the second memory node through the region WL5. The region WL5 is preferably electrically connected to the gate electrode RTrG[1] through the region WL6. The gate electrode RTrG[2] is electrically connected to the region WL8 functioning as the channel formation region of the transistor WTr[2] through the region WL7. The gate electrode RTrG[2] is preferably electrically connected to the region WL7 through the region WL6. The region WL8 is electrically connected to the wiring WBL1 through the region WL9 (not illustrated in FIG. 34).

Next, the wiring RL is described. One of the source and the drain of the selection transistor DTr2 is electrically connected to the wiring RBL2. The gate of the selection transistor DTr2 is electrically connected to the wiring RWL_D1.

The other of the source and the drain of the transistor DTr2 is electrically connected to the region RL2 functioning as the channel formation region of the transistor RTr[1] through the region RL1. The region RL2 is electrically connected to the region RL4 through the region RL3. The region RL4 functions as the back gate of the transistor WTr[1].

The region RL4 is electrically connected to the region RL6 functioning as the channel formation region of the transistor RTr[2] through the region RL5. The region RL6 is electrically connected to the region RL8 through the region RL7. The region RL8 functions as the back gate of the transistor WTr[2].

The region RL8 is electrically connected to one of the source and the drain of the selection transistor DTr3 through the region RL9 (not illustrated in FIG. 34). The gate of the selection transistor DTr3 is electrically connected to the wiring RWL_D2.

With use of the selection transistor DTr1 and the transistor WTr[2], the region WL1 to the region WL9 can be brought into a floating state. Moreover, with use of the selection transistor DTr2 and the selection transistor DTr3, the region RL1 to the region RL9 can be brought into a floating state.

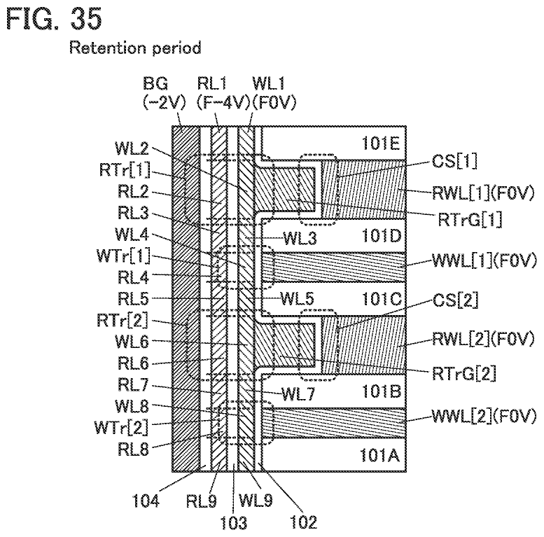

FIG. 35 to FIG. 40 are diagrams showing operation examples of the memory module.

An operation example in a data retention period of the memory cell included in the memory module is described with reference to FIG. 35. Potentials supplied to the wirings in the retention period are shown in the drawing as examples. Note that the potentials are examples and not limited. In addition, description of “F−4V” means that a wiring is supplied with −4 V, and then the wiring is brought into a floating state. As another example, description of “F0V” means that a wiring is supplied with 0 V, and then the wiring is brought into a floating state.

The capacitor CS[1] or the capacitor CS[2] is supplied with a potential of 0 V to 3 V as data, for example. The wiring BG is supplied with −2 V. The region RL1 included in the wiring RL is supplied with −4 V from the wiring RBL2 through the selection transistor DTr2. The region RL9 included in the wiring RL is supplied with −4 V from the wiring RBL1 through the selection transistor DTr3. After that, the selection transistor DTr2 and the selection transistor DTr3 are turned off, and the wiring RL is brought into a floating state. The wiring WL is supplied with 0 V from the wiring WBL1 through the selection transistor DTr1. After that, the selection transistor DTr1 and the transistor WTr[2] are turned off, and the wiring WL is brought into a floating state. The wiring WWL[1], the wiring RWL[1], the wiring WWL[2], and the wiring RWL[2] are supplied with 0 V, and then brought into a floating state.

As another example, in order to bring the wiring RL into a floating state, the wiring RBL1 and the wiring RBL2 may be brought into a floating state. In order to bring the wiring WL into a floating state, the wiring WBL1 may be brought into a floating state.

By making the potential of the wiring BG higher than the potential of the wiring RL, the resistance value of the wiring RL formed of a semiconductor layer becomes small. Therefore, the potential of −4 V supplied to the wiring RL is supplied to the region RL1, the region RL3, the region RL4, the region RL5, the region RL7, the region RL8, and the region RL9. At this time, parasitic capacitance is formed between the wiring BG and the wiring RL with the insulator 104 therebetween. In other words, by bringing the wiring RL into a floating state, a difference between the potentials supplied to the wiring BG and the wiring RL can be retained at the parasitic capacitance.

Since the region RL4 and the region RL8 function as the back gates of the transistor WTr[1] and the transistor WTr[2], the off-state current of each of the transistor WTr[1] and the transistor WTr[2] can be low. The back gates of the selection transistor DTr1, the selection transistor DTr2, and the selection transistor DTr3 are preferably supplied with a potential lower than a potential supplied to the wiring RL.

As another example, the wiring BG may be supplied with a potential lower than a potential supplied to the wiring RL. In the case where the wiring BG is supplied with a potential lower than a potential supplied to the wiring RL, the off-state current of the transistor RTr[1] or the transistor RTr[2] can be low.

The region RL4 functioning as the back gate of the transistor WTr[1] is supplied with a potential obtained by capacitive coupling of a potential supplied to the wiring BG through the above parasitic capacitance. Therefore, the back gate of the transistor WTr[1] is supplied with a lower potential. The same applies to the region RL8 functioning as the back gate of the transistor WTr[2].

Thus, the off-state current of the transistor WTr[1] or the transistor WTr[2] can be low. Accordingly, data stored in each memory node can be retained for a longer period.

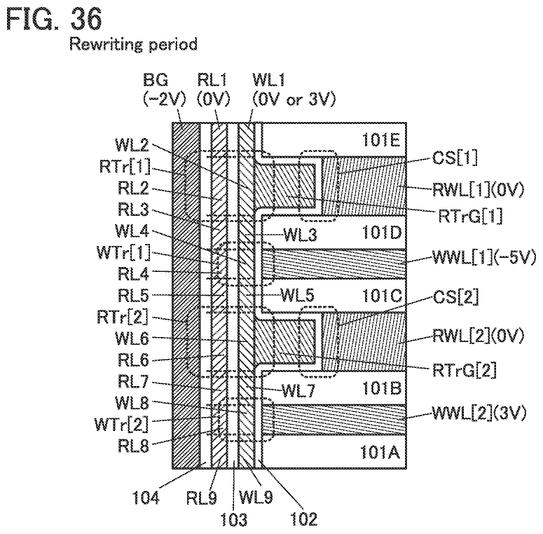

An operation example in a data rewriting period of the memory cell included in the memory module is described with reference to FIG. 36. Potentials supplied to the wirings in the rewriting period are shown in the drawing as examples. Note that the potentials are examples and not limited.

The region RL1 included in the wiring RL is supplied with 0 V from the wiring RBL2 through the selection transistor DTr2. The region RL9 included in the wiring RL is supplied with 0 V from the wiring RBL1 through the selection transistor DTr3. In a memory module in which data rewriting is performed, the region WL1 or the region WL9 included in the wiring WL is supplied with 3 V from the wiring WBL1 through the selection transistor DTr1. In a memory module in which data rewriting is not performed, the region WL1 or the region WL9 included in the wiring WL is supplied with 0 V from the wiring WBL1 through the selection transistor DTr1. The wiring BG is supplied with −2 V.

As an example, the case of rewriting data of the capacitor CS[2] through the region WL9 is described. The wiring WWL[1] is supplied with −5 V, the wiring RWL[1] is supplied with 0 V, the wiring WWL[2] is supplied with 3 V, and the wiring RWL[2] is supplied with 0 V. The transistor WTr[1] is turned off when the wiring WWL[1] is supplied with −5 V, and the transistor WTr[2] is turned on when the wiring WWL[2] is supplied with 3 V. Thus, the data of the capacitor CS[2] can be rewritten.

Although not illustrated, the case where rewriting data of the capacitor CS[1] through a region WLR9 is followed by rewriting data of the capacitor CS[2] is described as another example.

First, the wiring WWL[1] is supplied with 3 V, the wiring RWL[1] is supplied with 0 V, the wiring WWL[2] is supplied with 3 V, and the wiring RWL[2] is supplied with 0 V. The transistor WTr[1] is turned on when the wiring WWL[1] is supplied with 3 V, and the transistor WTr[2] is turned on when the wiring WWL[1] is supplied with 3 V. Thus, the data of the capacitor CS[1] can be rewritten.

Next, the case of rewriting data of the capacitor CS[2] through the region WLR9 is described. The wiring WWL[1] is supplied with −5 V, the wiring RWL[1] is supplied with 0 V, the wiring WWL[2] is supplied with 3 V, and the wiring RWL[2] is supplied with 0 V. The transistor WTr[1] is turned off when the wiring WWL[1] is supplied with −5 V, and the transistor WTr[2] is turned on when the wiring WWL[2] is supplied with 3 V. Thus, the data of the capacitor CS[2] can be rewritten.

Although not described in detail, data of the memory cell included in the above memory module may be rewritten through the region WL1.

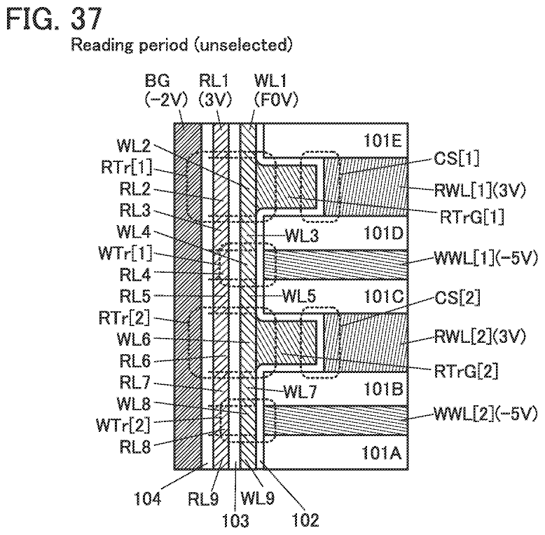

An operation example in a period (unselected) in which data is read from the memory cell included in the memory module is described with reference to FIG. 37. Potentials supplied to the wirings in the reading period are shown in the drawing as examples. Note that the potentials are examples and not limited.

The region WL1 and the region WL9 included in the wiring WL are supplied with 0 V through the wiring WBL1, and then brought into a floating state. Furthermore, it is preferable that the region RL1 included in the wiring RL be supplied with 3 V through the wiring RBL2, and the region RL9 included in the wiring RL be supplied with 0 V through the wiring RBL1 and then brought into a floating state. The wiring BG is supplied with −2 V.

Then, the wiring WWL[1] and the wiring WWL[2] are supplied with −5 V. The transistor WTr[1] is turned off when the wiring WWL[1] is supplied with −5 V. The transistor WTr[2] is turned off when the wiring WWL[2] is supplied with −5 V. Thus, data of the capacitor CS[1] and the capacitor CS[2] are retained.

Note that as an example, the case where 0 V is retained in the capacitor CS[1] and 3 V is retained in the capacitor CS[2] is described with reference to FIG. 37. The wiring RWL[1] and the wiring RWL[2] are supplied with 3 V.

A potential retained in the capacitor CS[1] changes from 0 V to 3 V by capacitive coupling by the capacitor CS[1]. The gate of the transistor RTr[1] is supplied with the potential retained in the capacitor CS[1]. Thus, the transistor RTr[1] is turned on.

A potential retained in the capacitor CS[2] changes from 3 V to 6 V by capacitive coupling by the capacitor CS[2]. The gate of the transistor RTr[2] is supplied with the potential retained in the capacitor CS[2]. Thus, the transistor RTr[2] is turned on.

Thus, when the wiring RWL[1] and the wiring RWL[2] are supplied with 3 V, the transistor RTr[1] and the transistor RTr[2] are turned on regardless of the volume of data retained in the capacitor CS. Therefore, in the case where the memory cell included in the memory module is unselected, a potential supplied to the wiring RBL2 is output to the region RL9 included in the wiring RL.

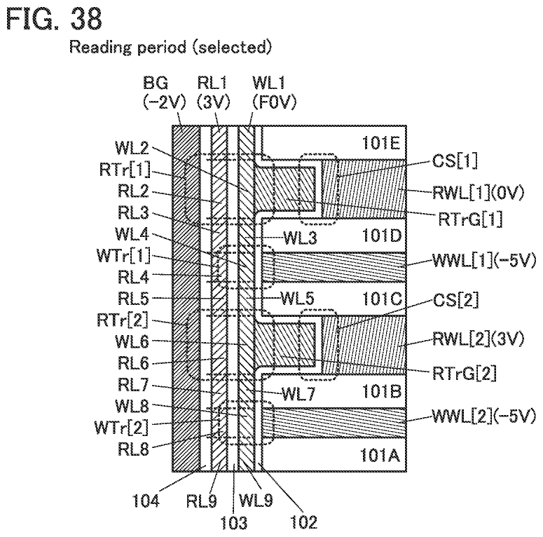

An operation example in a period (selected) in which data is read from the memory cell included in the memory module is described with reference to FIG. 38. Potentials supplied to the wirings in the reading period are shown in the drawing as examples. Note that the potentials are examples and not limited. FIG. 38 is different from FIG. 37 in that a potential supplied to the wiring RWL[1] is 0 V. Note that 0 V is retained in the capacitor CS[1] and 3 V is retained in the capacitor CS[2].

In a memory cell subjected to reading, the wiring RWL[1] is supplied with 0 V. In the case where the wiring RWL[1] is at 0 V, capacitive coupling through the capacitor CS[1] does not occur. Thus, a potential retained in the capacitor CS[1] is supplied to the gate of the transistor RTr[1]. Since the transistor RTr[1] is kept off, a potential supplied to the wiring RBL2 is not output to the region RL9 included in the wiring RL; thus, 0 V is maintained.

Furthermore, the wiring RWL[2] is supplied with 3 V. A potential retained in the capacitor CS[2] changes from 3 V to 6 V by capacitive coupling by the capacitor CS[2]. The gate of the transistor RTr[2] is supplied with the potential retained in the capacitor CS[2]. Thus, the transistor RTr[2] is turned on.

In the case where data retained in a selected memory cell is 3 V, a potential supplied to the wiring RBL2 is output to the region RL9 included in the wiring RL. As another example, in the case where data retained in a selected memory cell is 0 V, a potential supplied to the wiring RBL2 does not change from 0 V in the region RL9 included in the wiring RL.

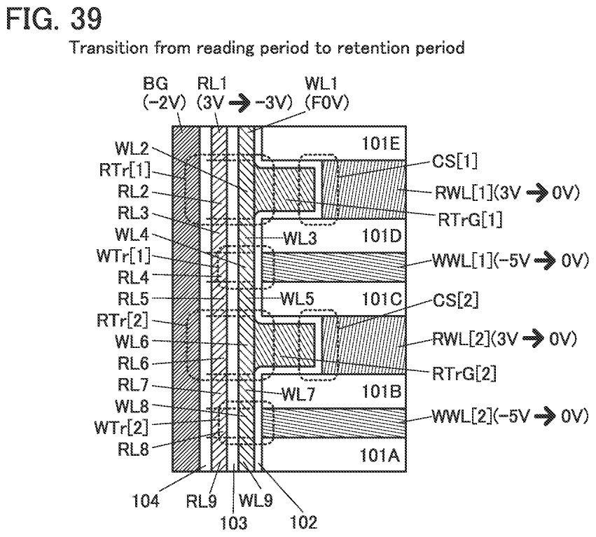

An example of transition operation from the data reading period in which data is read from the memory cell included in the memory module to the retention period is described with reference to FIG. 39. Potentials supplied to the wirings in the reading period and changes in the potentials in transition are shown in the drawing as examples. Note that the potentials are examples and not limited. The wiring BG is supplied with −2 V. The wiring RWL[1] and the wiring RWL[2] are supplied with 0 V. Note that 0 V is retained in the capacitor CS[1] and 3 V is retained in the capacitor CS[2].

First, a potential supplied to the region RL1 and the region RL9 included in the wiring RL is changed from 3 V to −3 V. Next, the wiring WWL[1] and the wiring WWL[2] are changed from −5 V to 0 V. Next, the wiring RWL[1] and the wiring RWL[2] are changed from 3 V to 0 V. Then, the wiring RL, the wiring RWL[1], the wiring RWL[2], the wiring WWL[1], and the wiring WWL[2] are brought into a floating state. The transistor RTr and the transistor WTr are OS transistors, and thus have low off-state current. Therefore, in the case where the memory module is subjected to power gating, deterioration of data retained in the capacitor CS[1] and the capacitor CS[2] can be suppressed even when the wiring RL, the wiring RWL[1], the wiring RWL[2], the wiring WWL[1], and the wiring WWL[2] are brought into a floating state.

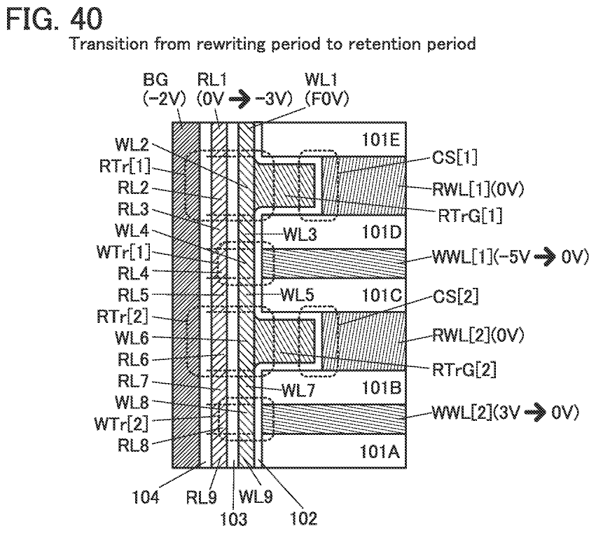

An example of transition operation from the data rewriting period in which data is rewritten in the memory cell included in the memory module to the retention period is described with reference to FIG. 40. Potentials supplied to the wirings in the rewriting period and changes in the potentials in transition are shown in the drawing as examples. Note that the potentials are examples and not limited. The wiring BG is supplied with −2 V. The wiring RWL[1] and the wiring RWL[2] are supplied with 0 V. Note that 0 V is retained in the capacitor CS[1] and 3 V is retained in the capacitor CS[2].

First, a potential supplied to the region WL1 and the region WL9 included in the wiring WL is changed from 0 V to −3 V. Next, the wiring WWL[1] is changed from −5 V to 0 V and the wiring WWL[2] is changed from 3 V to 0 V. Then, the wiring WL, the wiring WWL[1], the wiring WWL[2], the wiring RWL[1], and the wiring RWL[2] are brought into a floating state. The transistor RTr and the transistor WTr are OS transistors, and thus have low off-state current. Therefore, in the case where the memory module is subjected to power gating, deterioration of data retained in the capacitor CS[1] and the capacitor CS[2] can be suppressed even when the wiring WL, the wiring WWL[1], the wiring WWL[2], the wiring RWL[1], and the wiring RWL[2] are brought into a floating state.

The structure and method described in this embodiment can be used by being combined as appropriate with the structures and methods described in the other embodiments.

### Embodiment 4

In this embodiment, a CPU that can include the semiconductor device of the above embodiment will be described.

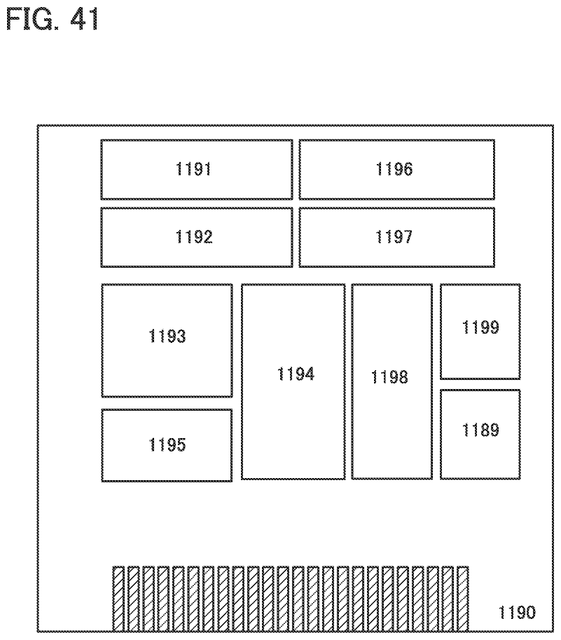

FIG. 41 is a block diagram illustrating a configuration example of a CPU in part of which the semiconductor device described in Embodiment 1 is used.

The CPU illustrated in FIG. 41 includes an ALU 1191 (ALU: Arithmetic logic unit), an ALU controller 1192, an instruction decoder 1193, an interrupt controller 1194, a timing controller 1195, a register 1196, a register controller 1197, a bus interface 1198 (Bus I/F), a rewritable ROM 1199, and a ROM interface 1189 (ROM I/F) over a substrate 1190. A semiconductor substrate, an SOI substrate, a glass substrate, or the like is used as the substrate 1190. The ROM 1199 and the ROM interface 1189 may be provided over separate chips. Needless to say, the CPU illustrated in FIG. 41 is just an example of a simplified configuration, and an actual CPU may have a variety of configurations depending on the usage. For example, the CPU may have a configuration in which a configuration including the CPU illustrated in FIG. 41 or an arithmetic circuit is considered as one core, a plurality of the cores are included, and the cores operate in parallel, namely a configuration like that of a GPU. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal based on a reference clock signal, and supplies the internal clock signal to the above circuits.

In the CPU illustrated in FIG. 41, a memory cell is provided in the register 1196. As the memory cell of the register 1196, the transistors described in the above embodiments can be used.

In the CPU illustrated in FIG. 41, the register controller 1197 selects a retaining operation in the register 1196 in accordance with an instruction from the ALU 1191. That is, the register controller 1197 selects whether data retaining by a flip-flop is performed or data retaining by a capacitor is performed in the memory cell included in the register 1196. In the case where data retaining by the flip-flop is selected, a power supply voltage is supplied to the memory cell in the register 1196. In the case where data retaining by the capacitor is selected, the data is rewritten into the capacitor, and supply of a power supply voltage to the memory cell in the register 1196 can be stopped.

Note that this embodiment can be combined as appropriate with the other embodiments shown in this specification.

### Embodiment 5

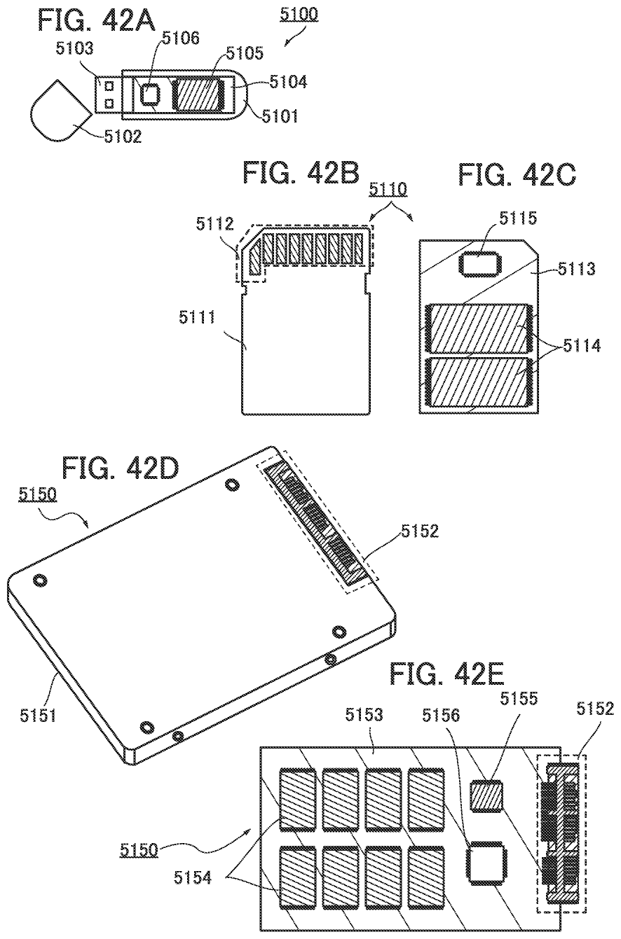

The memory device of the above embodiment can be applied to a variety of removable memory devices such as a memory card (for example, an SD card), a USB (Universal Serial Bus) memory, and an SSD (Solid State Drive). In this embodiment, some structure examples of the removable memory devices will be described with reference to FIG. 42.

FIG. 42A is a schematic diagram of a USB memory. A USB memory 5100 includes a housing 5101, a cap 5102, a USB connector 5103, and a substrate 5104. The substrate 5104 is held in the housing 5101. The substrate 5104 is provided with a memory device and a circuit for driving the memory device. For example, a memory chip 5105 and a controller chip 5106 are attached to the substrate 5104. The memory cell array 2610, the word line driver circuit 2622, the row decoder 2621, the sense amplifier 2633, the precharge circuit 2632, the column decoder 2631, and the like, which are described in Embodiment 2, are incorporated in the memory chip 5105. Specifically, a processor, a work memory, an ECC circuit, and the like are incorporated in the controller chip 5106. Note that the circuit configurations of the memory chip 5105 and the controller chip 5106 are not limited to those described above, and the circuit configurations can be changed as appropriate according to circumstances or depending on the case. For example, the word line driver circuit 2622, the row decoder 2621, the sense amplifier 2633, the precharge circuit 2632, and the column decoder 2631 may be incorporated in not the memory chip 5105 but the controller chip 5106. The USB connector 5103 functions as an interface for connection to an external device.

FIG. 42B is a schematic external view of an SD card, and FIG. 42C is a schematic diagram illustrating the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, a memory chip 5114 and a controller chip 5115 are attached to the substrate 5113. The memory cell array 2610, the word line driver circuit 2622, the row decoder 2621, the sense amplifier 2633, the precharge circuit 2632, the column decoder 2631, and the like, which are described in Embodiment 2, are incorporated in the memory chip 5114. A processor, a work memory, an ECC circuit, and the like are incorporated in the controller chip 5115. Note that the circuit configurations of the memory chip 5114 and the controller chip 5115 are not limited to those described above, and the circuit configurations can be changed as appropriate according to circumstances or depending on the case. For example, the word line driver circuit 2622, the row decoder 2621, the sense amplifier 2633, the precharge circuit 2632, and the column decoder 2631 may be incorporated in not the memory chip 5114 but the controller chip 5115.

When the memory chip 5114 is provided also on a rear surface side of the substrate 5113, the capacity of the SD card 5110 can be increased. In addition, a wireless chip with a wireless communication function may be provided on the substrate 5113. By this, wireless communication between an external device and the SD card 5110 can be conducted, which enables data reading and writing from/to the memory chip 5114.

FIG. 42D is a schematic external view of an SSD, and FIG. 42E is a schematic diagram illustrating the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, a memory chip 5154, a memory chip 5155, and a controller chip 5156 are attached to the substrate 5153. The memory cell array 2610, the word line driver circuit 2622, the row decoder 2621, the sense amplifier 2633, the precharge circuit 2632, the column decoder 2631, and the like, which are described in Embodiment 2, are incorporated in the memory chip 5154. When the memory chip 5154 is also provided on a rear surface side of the substrate 5153, the capacity of the SSD 5150 can be increased. A work memory is incorporated in the memory chip 5155. For example, a DRAM chip may be used as the memory chip 5155. A processor, an ECC circuit, and the like are incorporated in the controller chip 5156. Note that the circuit configurations of the memory chip 5154, the memory chip 5155, and the controller chip 5115 are not limited to those described above, and the circuit configurations can be changed as appropriate according to circumstances or depending on the case. For example, a memory functioning as a work memory may also be provided in the controller chip 5156.

Note that this embodiment can be combined as appropriate with the other embodiments shown in this specification.

### Embodiment 6

In this embodiment, examples of electronic devices in which the semiconductor device or the memory device of the above embodiment can be used will be described.

### <Laptop Personal Computer>

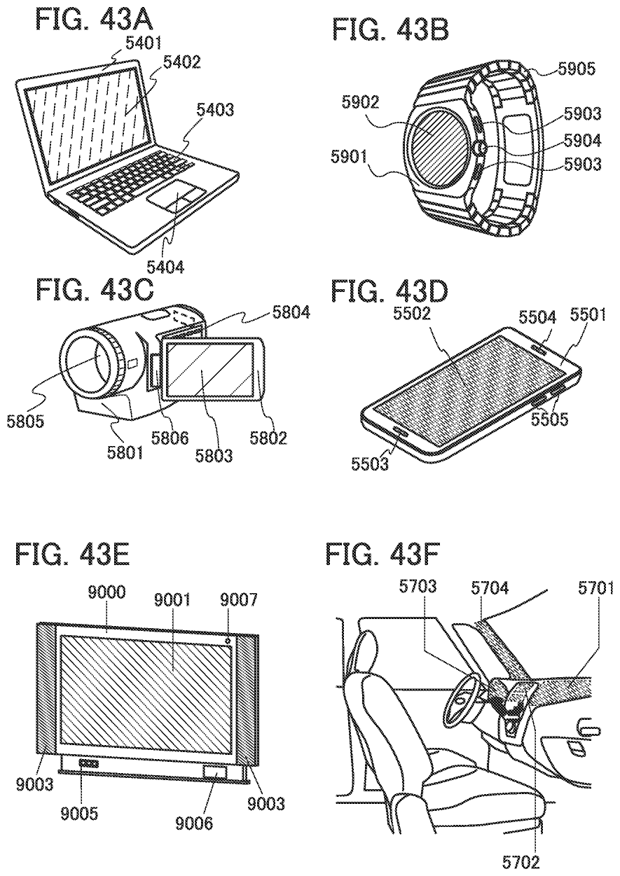

FIG. 43A illustrates a laptop personal computer including a housing 5401, a display portion 5402, a keyboard 5403, a pointing device 5404, and the like. The memory device of one embodiment of the present invention can be provided in the laptop personal computer.

### <Smartwatch (Registered Trademark)>

FIG. 43B illustrates a smartwatch that is one of wearable terminals, including a housing 5901, a display portion 5902, operation buttons 5903, an operator 5904, a band 5905, and the like. The memory device of one embodiment of the present invention can be provided in the smartwatch. A display device with a function of a position input device may be used for the display portion 5902. The function of the position input device can be added by provision of a touch panel in a display device. Alternatively, the function of the position input device can be added by provision of a photoelectric conversion element called a photosensor in a pixel portion of a display device. As the operation buttons 5903, any of a power switch for activating the smartwatch, a button for operating an application of the smartwatch, a volume control button, a switch for turning on or off the display portion 5902, and the like can be provided. Although the number of the operation buttons 5903 is two in the smartwatch illustrated in FIG. 43B, the number of the operation buttons included in the smartwatch is not limited thereto. The operator 5904 functions as a crown used for adjusting the time on the smartwatch. The operator 5904 may be used as an input interface for operating an application of the smartwatch as well as the crown for time adjustment. Although the smartwatch illustrated in FIG. 43B includes the operator 5904, without being limited thereto, the smartwatch does not necessarily include the operator 5904.

### <Video Camera>

FIG. 43C illustrates a video camera including a first housing 5801, a second housing 5802, a display portion 5803, operation keys 5804, a lens 5805, a joint 5806, and the like. The memory device of one embodiment of the present invention can be provided in the video camera. The operation keys 5804 and the lens 5805 are provided in the first housing 5801, and the display portion 5803 is provided in the second housing 5802. Furthermore, the first housing 5801 and the second housing 5802 are connected to each other with the joint 5806, and the angle between the first housing 5801 and the second housing 5802 can be changed with the joint 5806. Images on the display portion 5803 may be changed in accordance with the angle at the joint 5806 between the first housing 5801 and the second housing 5802.

### <Mobile Phone>

FIG. 43D illustrates a mobile phone having a function of an information terminal, including a housing 5501, a display portion 5502, a microphone 5503, a speaker 5504, and operation buttons 5505. The memory device of one embodiment of the present invention can be provided in the mobile phone. A display device with a function of a position input device may be used for the display portion 5502. The function of the position input device can be added by provision of a touch panel in a display device. Alternatively, the function of the position input device can be added by provision of a photoelectric conversion element called a photosensor in a pixel portion of a display device. As the operation buttons 5505, any of a power switch for activating the mobile phone, a button for operating an application of the mobile phone, a volume control button, a switch for turning on or off the display portion 5502, and the like can be provided.

Although the number of the operation buttons 5505 is two in the mobile phone illustrated in FIG. 43D, the number of the operation buttons included in the mobile phone is not limited thereto. Although not illustrated, the mobile phone illustrated in FIG. 43D may include a light-emitting device used for a flashlight or a lighting purpose.

### <Television Device>

FIG. 43E is a perspective view illustrating a television device. The television device includes a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, an odor, or infrared rays), and the like. The memory device of one embodiment of the present invention can be provided in the television device. The television device can include the display portion 9001 having a large screen size of, for example, 50 inches or more, or 100 inches or more.

### <Vehicle>

The above-described memory device can also be used around a driver's seat in a car, which is a vehicle.

For example, FIG. 43F illustrates a windshield and its vicinity inside a car. FIG. 43F illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying navigation information, a speedometer, a tachometer, a mileage, a fuel meter, a gearshift indicator, air-condition settings, and the like. The content, layout, or the like of the display on the display panels can be changed freely to suit the user's preferences, so that the design can be improved. The display panel 5701 to the display panel 5703 can also be used as lighting devices.

The display panel 5704 can compensate for the view obstructed by the pillar (blind areas) by showing an image taken by an imaging unit provided for the car body. That is, showing an image taken by an imaging unit provided on the outside of the car body leads to elimination of blind areas and enhancement of safety. In addition, showing an image so as to compensate for the area which a driver cannot see makes it possible for the driver to confirm safety easily and comfortably. The display panel 5704 can also be used as a lighting device.

The memory device of one embodiment of the present invention can be provided in the vehicle. The memory device of one embodiment of the present invention can be used, for example, for a frame memory that temporarily stores image data used to display images on the display panel 5701 to the display panel 5704, or for a memory device that stores a program for driving a system included in the vehicle.

Although not illustrated, each of the electronic devices illustrated in FIG. 43A to FIG. 43C, FIG. 43E, and FIG. 43F may include a microphone and a speaker. With this structure, the above electronic devices can have an audio input function, for example.

Although not illustrated, each of the electronic devices illustrated in FIG. 43A, FIG. 43B, and FIG. 43D to FIG. 43F may include a camera.

Although not illustrated, each of the electronic devices illustrated in FIG. 43A to FIG. 43F may include a sensor (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, an odor, infrared rays, or the like) in the housing. In particular, when the mobile phone illustrated in FIG. 43D is provided with a sensing device which includes a sensor for sensing inclinations, such as a gyroscope sensor or an acceleration sensor, the orientation of the mobile phone (the orientation of the mobile phone with respect to the vertical direction) is determined and display on the screen of the display portion 5502 can be automatically changed in accordance with the orientation of the mobile phone.

Although not illustrated, each of the electronic devices illustrated in FIG. 43A to FIG. 43F may include a device for obtaining biological information such as fingerprints, veins, irises, or voice prints. Employing this structure can achieve an electronic device having a biometric identification function.

A flexible base may be used for the display portion of each of the electronic devices illustrated in FIG. 43A to FIG. 43F. Specifically, the display portion may have a structure in which a transistor, a capacitor, a display element, and the like are provided over a flexible base. Employing this structure can achieve not only an electronic device having a housing with a flat surface as in the electronic devices illustrated in FIG. 43A to FIG. 43F but also an electronic device having a housing with a curved surface.

Note that this embodiment can be combined as appropriate with the other embodiments shown in this specification.

(Notes on the Description in this Specification and the Like)

The following are notes on the description of the structures in the above embodiments.

### Notes on One Embodiment of the Present Invention Described in Embodiments

One embodiment of the present invention can be constituted by combining, as appropriate, the structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described with reference to a variety of drawings or a content described with text disclosed in the specification.

Note that by combining a drawing (or part thereof) described in one embodiment with at least one of another part of the drawing, a different drawing (or part thereof) described in the embodiment, and a drawing (or part thereof) described in one or a plurality of different embodiments, much more drawings can be constituted.

### <Notes on Ordinal Numbers>

Ordinal numbers such as “first”, “second”, and “third” in this specification and the like are used in order to avoid confusion among components. Thus, the ordinal numbers do not limit the number of components. Furthermore, the ordinal numbers do not limit the order of components. In this specification and the like, for example, a “first” component in one embodiment can be referred to as a “second” component in other embodiments or the scope of claims. Furthermore, in this specification and the like, for example, a “first” component in one embodiment can be omitted in other embodiments or the scope of claims.

### <Notes on Description for Drawings>

Embodiments are described with reference to drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted.

Moreover, in this specification and the like, terms for describing arrangement, such as “over” and “under”, are used for convenience for describing the positional relation between components with reference to drawings. The positional relation between components is changed as appropriate in accordance with a direction in which the components are illustrated. Thus, terms for describing arrangement are not limited to those described in this specification and can be rephrased as appropriate according to circumstances.

Furthermore, the term “over” or “under” does not necessarily mean that a component is placed directly above or directly below and in direct contact with another component. For example, the expression “an electrode B over an insulating layer A” does not necessarily mean that the electrode B is formed on and in direct contact with the insulating layer A and does not exclude the case where another component is provided between the insulating layer A and the electrode B.

In drawings, the size, the layer thickness, or the region is shown arbitrarily for description convenience. Therefore, they are not limited to the scale. Note that the drawings are schematically shown for clarity, and embodiments of the present invention are not limited to shapes or values shown in the drawings. For example, variation in signal, voltage, or current due to noise or variation in signal, voltage, or current due to difference in timing can be included.

In drawings such as a perspective view, illustration of some components is in some cases omitted for clarity of the drawings.

Moreover, the same components or components having similar functions, components formed using the same material, components formed at the same time, or the like in the drawings are denoted by the same reference numerals in some cases, and the repeated description thereof is omitted in some cases.

<Notes on Expressions that can be Rephrased>

In this specification and the like, expressions “one of a source and a drain” (or a first electrode or a first terminal) and “the other of the source and the drain” (or a second electrode or a second terminal) are used in the description of the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate according to circumstances. In this specification and the like, the two terminals other than the gate are referred to as a first terminal and a second terminal or as a third terminal and a fourth terminal in some cases. Note that in this specification and the like, a channel formation region refers to a region where a channel is formed by application of a potential to the gate, and the formation of this region enables current to flow between the source and the drain.

Furthermore, functions of a source and a drain are sometimes interchanged with each other when transistors having different polarities are used or when the direction of current is changed in circuit operation, for example. Therefore, the terms of source and drain can be interchanged in this specification and the like.

Furthermore, in the case where a transistor described in this specification and the like has two or more gates (such a structure is referred to as a dual-gate structure in some cases), these gates are referred to as a first gate and a second gate or as a front gate and a back gate in some cases. In particular, the term “front gate” can be replaced with a simple term “gate”. In addition, the term “back gate” can be replaced with a simple term “gate”. Note that a bottom gate is a terminal that is formed before a channel formation region in manufacture of a transistor, and a “top gate” is a terminal that is formed after a channel formation region in manufacture of a transistor.

In addition, in this specification and the like, the term “electrode” or “wiring” does not functionally limit a component. For example, an “electrode” is sometimes used as part of a “wiring”, and vice versa. Furthermore, the term “electrode” or “wiring” can also mean the case where a plurality of “electrodes” or “wirings” are formed in an integrated manner.

In this specification and the like, voltage and potential can be replaced with each other as appropriate. Voltage refers to a potential difference from a reference potential, and when the reference potential is a ground potential, for example, voltage can be replaced with potential. The ground potential does not necessarily mean 0 V. Note that potentials are relative, and the potential supplied to a wiring or the like is changed depending on the reference potential, in some cases.

Note that in this specification and the like, the terms “film”, “layer”, and the like can be interchanged with each other depending on the case or according to circumstances. For example, the term “conductive layer” can be changed into the term “conductive film” in some cases. Moreover, the term “insulating film” can be changed into the term “insulating layer” in some cases. Alternatively, the term “film”, “layer”, or the like is not used and can be interchanged with another term depending on the case or according to circumstances. For example, the term “conductive layer” or “conductive film” can be changed into the term “conductor” in some cases. Furthermore, for example, the term “insulating layer” or “insulating film” can be changed into the term “insulator” in some cases.

Note that in this specification and the like, the terms “wiring”, “signal line”, “power source line”, and the like can be interchanged with each other depending on the case or according to circumstances. For example, the term “wiring” can be changed into the term “signal line” in some cases. Also, for example, the term “wiring” can be changed into the term “power source line” in some cases. Inversely, the term “signal line”, “power source line”, or the like can be changed into the term “wiring” in some cases. The term “power source line” or the like can be changed into the term “signal line” or the like in some cases. Inversely, the term “signal line” or the like can be changed into the term “power source line” or the like in some cases. The term “potential” that is applied to a wiring can be changed into the term “signal” or the like depending on the case or according to circumstances. Inversely, the term “signal” or the like can be changed into the term “potential” in some cases.

### <Notes on Definitions of Terms>

Definitions of the terms mentioned in the above embodiments will be described below.

### <<Impurity in Semiconductor>>

An impurity in a semiconductor refers to, for example, an element other than the main components of a semiconductor layer. For example, an element with a concentration of lower than 0.1 atomic % is an impurity. If a semiconductor contains an impurity, formation of the DOS (Density of States) in the semiconductor, decrease in the carrier mobility, or decrease in the crystallinity occurs in some cases, for example. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components; specifically, there are hydrogen (contained also in water), lithium, sodium, silicon, boron, phosphorus, carbon, and nitrogen, for example. In the case of an oxide semiconductor, oxygen vacancies may be formed by entry of impurities such as hydrogen. Moreover, in the case where the semiconductor is a silicon layer, examples of an impurity which changes characteristics of the semiconductor include oxygen, Group 1 elements except hydrogen, Group 2 elements, Group 13 elements, and Group 15 elements.

### <<Switch>>

In this specification and the like, a switch is in a conduction state (on state) or in a non-conduction state (off state) to determine whether current flows or not. Alternatively, a switch has a function of selecting and changing a current path.

Examples of the switch that can be used are an electrical switch, a mechanical switch, and the like. That is, a switch can be any element capable of controlling current, and is not limited to a certain element.

Examples of the electrical switch include a transistor (for example, a bipolar transistor or a MOS transistor), a diode (for example, a PN diode, a PIN diode, a Schottky diode, a MIM (Metal Insulator Metal) diode, a MIS (Metal Insulator Semiconductor) diode, or a diode-connected transistor), and a logic circuit in which such elements are combined.

Note that in the case of using a transistor as a switch, a “conduction state” of the transistor refers to a state where a source electrode and a drain electrode of the transistor can be regarded as being electrically short-circuited. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of the mechanical switch is a switch formed using a MEMS (micro electro mechanical system) technology, such as a digital micromirror device (DMD). Such a switch includes an electrode which can be moved mechanically, and operates by controlling conduction and non-conduction with movement of the electrode.

### <<Connection>>

In this specification and the like, a description X and Y are connected includes the case where X and Y are electrically connected, the case where X and Y are functionally connected, and the case where X and Y are directly connected. Accordingly, without being limited to a predetermined connection relation, for example, a connection relation shown in drawings or text, a connection relation other than the connection relation shown in drawings or text is also included.

Note that X, Y, and the like used here are each an object (for example, a device, an element, a circuit, a wiring, an electrode, a terminal, a conductive film, or a layer).

For example, in the case where X and Y are electrically connected, one or more elements that enable electrical connection between X and Y (for example, a switch, a transistor, a capacitor, an inductor, a resistor, a diode, a display element, a light-emitting element, or a load) can be connected between X and Y. Note that the switch has a function of being controlled to be turned on or off. That is, the switch has a function of being in a conduction state (on state) or a non-conduction state (off state) to determine whether current flows or not.

For example, in the case where X and Y are functionally connected, one or more elements that enable functional connection between X and Y (for example, a logic circuit (an inverter, a NAND circuit, a NOR circuit, or the like); a signal converter circuit (a DA converter circuit, an AD converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; or a control circuit) can be connected between X and Y. Note that, for example, even when another circuit is interposed between X and Y, X and Y are functionally connected if a signal output from Xis transmitted to Y.

Note that an explicit description that X and Y are electrically connected includes the case where X and Y are electrically connected (that is, the case where X and Y are connected with another element or another circuit provided therebetween), the case where X and Y are functionally connected (that is, the case where X and Y are functionally connected with another circuit provided therebetween), and the case where X and Y are directly connected (that is, the case where X and Y are connected without another element or another circuit provided therebetween). That is, the explicit expression that X and Y are electrically connected is the same as the explicit simple expression that X and Y are connected.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y can be expressed as follows.

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit configuration is defined by using an expression similar to these examples, a source (or a first terminal or the like) and a drain (or a second terminal or the like) of a transistor can be distinguished from each other to specify the technical scope. Note that these expressions are examples and expressions are not limited to these expressions. Here, each of X, Y, Z1, and Z2 is an object (for example, a device, an element, a circuit, a wiring, an electrode, a terminal, a conductive film, or a layer).

Note that even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification also includes in its category such a case where one conductive film has functions of a plurality of components.

### <<Parallel and Perpendicular>>

In this specification, “parallel” indicates a state where the angle formed between two straight lines is greater than or equal to −10° and less than or equal to 10°. Accordingly, the case where the angle is greater than or equal to −5° and less than or equal to 5° is also included. In addition, “substantially parallel” indicates a state where the angle formed between two straight lines is greater than or equal to −30° and less than or equal to 30°. In addition, “perpendicular” indicates a state where the angle formed between two straight lines is greater than or equal to 80° and less than or equal to 100°. Accordingly, the case where the angle is greater than or equal to 85° and less than or equal to 95° is also included. In addition, “substantially perpendicular” indicates a state where the angle formed between two straight lines is greater than or equal to 60° and less than or equal to 120°.

### REFERENCE NUMERALS

DM1: region, DM2: region, DTr1: selection transistor, DTr2: selection transistor, DTr3: selection transistor, RBL1: wiring, RBL2: wiring, RL1: region, RL2: region, RL3: region, RL4: region, RL5: region, RL6: region, RL7: region, RL8: region, RL9: region, RW2: region, RW4: region, RW6: region, RW8: region, RWL_D1: wiring, RWL_D2: wiring, WWL_D: wiring, SD1: region, SD2: region, WBL1: wiring, WBL1a: wiring, WBL2: wiring, WL1: region, WL2: region, WL3: region, WL4: region, WL5: region, WL6: region, WL7: region, WL8: region, WL9: region, WLR9: region, WWL4: region, 10: memory module, 100: stack, 101: insulating layer, 101A: insulator, 101B: insulator, 101C: insulator, 101D: insulator, 101E: insulator, 102: insulator, 103: insulator, 104: insulator, 105: insulator, 131A: conductor, 131B: conductor, 132A: conductor, 132B: conductor, 133: conductor, 133a: conductor, 133b: conductor, 133c: conductor, 134: conductor, 151: semiconductor, 151a: region, 151b: region, 151c: region, 152: semiconductor, 153: semiconductor, 153a: semiconductor, 153b: semiconductor, 181A: region, 181B: region, 182A: region, 182B: region, 183A: region, 183B: region, 191: opening, 192A: recess portion, 192B: recess portion, 193A: recess portion, 193B: recess portion, 194A: recess portion, 194B: recess portion, 194C: recess portion, 1000: logic layer, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 1700: substrate, 1701: element isolation layer, 1712: conductor, 1730: conductor, 1790: gate electrode, 1792: well, 1793: channel formation region, 1794: low-concentration impurity region, 1795: high-concentration impurity region, 1796: conductive region, 1797: gate insulating film, 1798: sidewall insulating layer, 1799: sidewall insulating layer, 2000: memory layer, 2600: memory device, 2601: peripheral circuit, 2610: memory cell array, 2621: row decoder, 2622: word line driver circuit, 2630: bit line driver circuit, 2630A: bit line driver circuit, 2630B: bit line driver circuit, 2631: column decoder, 2632: precharge circuit, 2633: sense amplifier, 2634: circuit, 2640: output circuit, 2660: control logic circuit, 5100: USB memory, 5101: housing, 5102: cap, 5103: USB connector, 5104: substrate, 5105: memory chip, 5106: controller chip, 5110: SD card, 5111: housing, 5112: connector, 5113: substrate, 5114: memory chip, 5115: controller chip, 5150: SSD, 5151: housing, 5152: connector, 5153: substrate, 5154: memory chip, 5155: memory chip, 5156: controller chip, 5401: housing, 5402: display portion, 5403: keyboard, 5404: pointing device, 5501: housing, 5502: display portion, 5503: microphone, 5504: speaker, 5505: operation button, 5701: display panel, 5702: display panel, 5703: display panel, 5704: display panel, 5801: housing, 5802: housing, 5803: display portion, 5804: operation key, 5805: lens, 5806: joint, 5901: housing, 5902: display portion, 5903: operation button, 5904: operator, 5905: band, 9000: housing, 9001: display portion, 9003: speaker, 9005: operation key, 9006: connection terminal, 9007: sensor

1. A semiconductor device comprising:
a memory module comprising:
a first memory cell; and
first to third wirings,
wherein the second wiring and the third wiring each comprise a metal oxide,
wherein the first memory cell comprises a first read transistor and a first rewrite transistor,
wherein the first wiring comprises a region serving as a back gate of the first read transistor and a region where the second wiring serves as a conductor,
wherein the second wiring comprises a region serving as a channel formation region of the first read transistor, a region serving as a back gate of the first rewrite transistor, and a region where the third wiring serves as a conductor, and
wherein the third wiring comprises a region serving as a channel formation region of the first rewrite transistor and a region serving as a conductor.

2. The semiconductor device according to claim 1,
wherein the first rewrite transistor and the first read transistor are formed in the same opening, and
wherein the second wiring comprising the channel formation region of the first read transistor is formed inward from the third wiring comprising the channel formation region of the first rewrite transistor, with an insulating layer therebetween.

3. An electronic device comprising the semiconductor device according to claim 1 and a housing.
